(19) United States
(12) Patent Application Publication
(10) Pub. No.: US 2018/0337354 A1
(43) Pub. Date: Nov. 22, 2018

(54) ORGANIC EL DISPLAY DEVICE

(71) Applicant: Sharp Kabushiki Kaisha, Sakai City, Osaka (JP)

(72) Inventors: Tohru SONODA, Sakai City (JP); Takeshi HIRASE, Sakai City (JP); Tohru SENOO, Sakai City (JP); Takashi OCHI, Sakai City (JP); Mamoru ISHIDA, Sakai City (JP)

(21) Appl. No.: 15/777,232

(22) PCT Filed: Feb. 1, 2017
(86) PCT No.: PCT/JP2017/003615

§ 371 Date: May 18, 2018

(30) Foreign Application Priority Data
Feb. 8, 2016 (JP) 2016-021636

(51) Int. Cl. H01L 51/00; H01L 27/32; H01L 51/52

(52) U.S. Cl. CPC H01L 51/0097; H01L 27/3244; H01L 27/323; G06F 3/044; H01L 51/5253; H01L 51/5281; H01L 2251/5338; H01L 27/322

(57) ABSTRACT

Disclosed herein is an organic EL display device including: a base resin substrate layer (10); an organic EL element layer (20) provided on the base resin substrate layer (10); an underlayer (29) provided on the organic EL element layer (20); and a hard coat layer (30) provided on the underlayer (29). A difference between a Martens hardness of the hard coat layer (30) alone and a weighted average Martens hardness of components of a stack layer by stress dispersion coefficients of the components is less than or equal to 79 N/mm². The stack layer includes the base resin substrate layer, the organic EL element layer, and the underlayer.

### TECHNICAL FIELD

The present invention relates to an organic EL display device.

### BACKGROUND ART

Self-luminous organic EL display devices including an organic electroluminescence (EL) element have recently received attention, as display devices alternative to liquid crystal display devices. As an organic EL display device of this type, a repeatedly bendable organic EL display device including a flexible resin substrate, and an organic EL element and various films stacked on the resin substrate has been proposed. Such a repeatedly bendable organic EL display device has been proposed to include a hard coat layer on its outermost surface so that even if a pressure is applied to a display screen by, for example, a pencil, the display screen is less likely to suffer from a permanent plastic deformation (flaw).

For example, Patent Document 1 discloses an optical stack including a triacetylcellulose substrate, and a hard coat layer on one surface of the triacetylcellulose substrate. The Martens hardness of a surface of the hard coat layer, the Martens hardness of a central portion of a cross section of the hard coat layer, and the Martens hardness of a central portion of a cross section of the triacetylcellulose substrate are each defined in a predetermined range.

### CITATION LIST

### Patent Documents

Patent Document 1: International Publication No. WO 2012/026497

### SUMMARY OF THE INVENTION

### Technical Problem

Even if an organic EL display device includes a hard coat layer on its outermost surface (its surface), an increase in the pressure applied to the hard coat layer may cause an underlayer under the hard coat layer to be plastically deformed, for example. This may cause the hard coat layer on the outermost surface to suffer from a permanent plastic deformation (flaw). This causes the reflection of natural light entering a display screen or light emitted from an organic EL element to scatter due to the flaw occurring on the surface of the hard coat layer. This degrades the display quality of the organic EL display device.

In view of the foregoing background, it is therefore an object of the present invention to reduce the plastic deformation of a hard coat layer forming a surface of an organic EL display device.

### Solution to the Problem

To achieve the above object, an organic EL display device according to the present invention includes: a base resin substrate layer; an organic EL element layer provided on the base resin substrate layer; an underlayer provided on the organic EL element layer; and a hard coat layer provided on the underlayer. A difference between a Martens hardness of the hard coat layer alone and a weighted average Martens hardness of components of a stack layer by stress dispersion coefficients of the components is less than or equal to 79 N/mm², the stack layer including the base resin substrate layer, the organic EL element layer, and the underlayer.

### Advantages of the Invention

According to the present invention, the difference between the Martens hardness of a hard coat layer alone and the weighted average Martens hardness of components of a stack layer below the hard coat layer by stress dispersion coefficients of the components is less than or equal to 79 N/mm². This can reduce plastic deformation of the hard coat layer forming a surface of an organic EL display device.

### BRIEF DESCRIPTION OF THE DRAWINGS

FIG. 1 is a plan view showing a pixel structure of an organic EL display device according to a first embodiment of the present invention.

FIG. 2 is a cross-sectional view of the organic EL display device taken along line II-II shown in FIG. 1.

FIG. 3 is an equivalent circuit diagram of an organic EL element layer forming part of the organic EL display device according to the first embodiment of the present invention.

FIG. 4 is a cross-sectional view of an organic EL layer forming part of the organic EL display device according to the first embodiment of the present invention.

FIG. 5 is a schematic diagram for explaining the distance from a surface of a hard coat layer of the organic EL display device according to the first embodiment of the present invention, where the distance is used to determine a stress dispersion coefficient.

FIG. 6 is a table showing specific information on an organic EL display device according to the first embodiment of the present invention which was fabricated as a first example.

FIG. 7 is a cross-sectional view of an organic EL display device according to a second embodiment of the present invention.

FIG. 8 is a table showing specific information on an organic EL display device according to the second embodiment of the present invention which was fabricated as a second example.

FIG. 9 is a cross-sectional view of an organic EL display device according to a third embodiment of the present invention.

FIG. 10 is a table showing specific information on an organic EL display device according to the third embodiment of the present invention which was fabricated as a third example.

FIG. 11 is a cross-sectional view of an organic EL display device according to a fourth embodiment of the present invention.

FIG. 12 is a table showing specific information on an organic EL display device according to the fourth embodiment of the present invention which was fabricated as a fourth example.

FIG. 13 is a cross-sectional view of an organic EL display device according to a fifth embodiment of the present invention.

FIG. 14 is a table showing specific information on an organic EL display device according to the fifth embodiment of the present invention which was fabricated as a fifth example.

FIG. 15 is a table showing specific information on an organic EL display device according to the fifth embodiment of the present invention which was fabricated as a first comparative example.

FIG. 16 is a table showing specific information on an organic EL display device according to the fifth embodiment of the present invention which was fabricated as a second comparative example.

### DESCRIPTION OF EMBODIMENTS

Embodiments of the present invention will now be described in detail with reference to the drawings. Note that the present invention is not limited to the following embodiments.

### First Embodiment

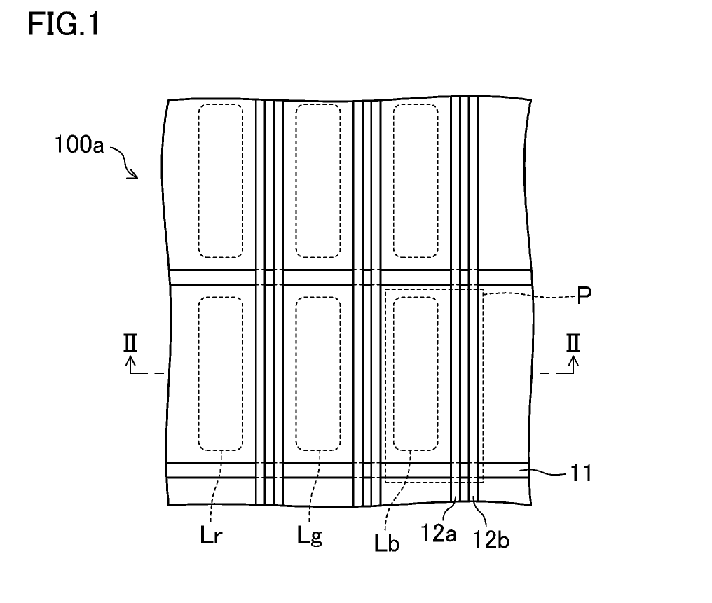

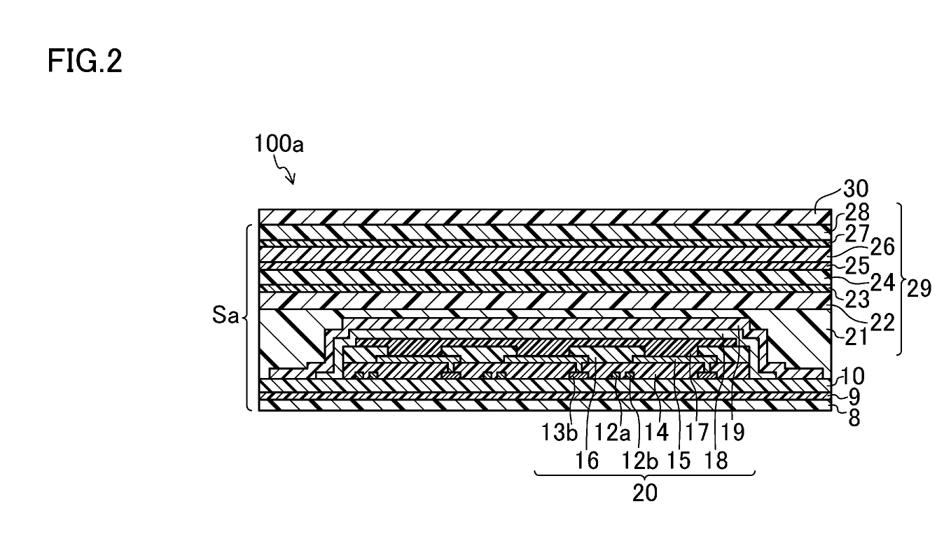

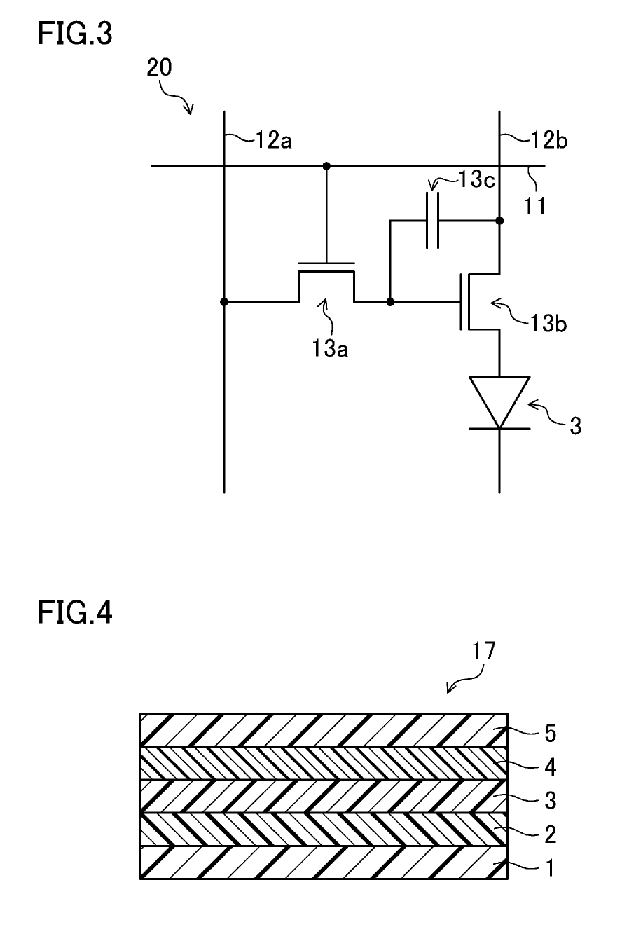

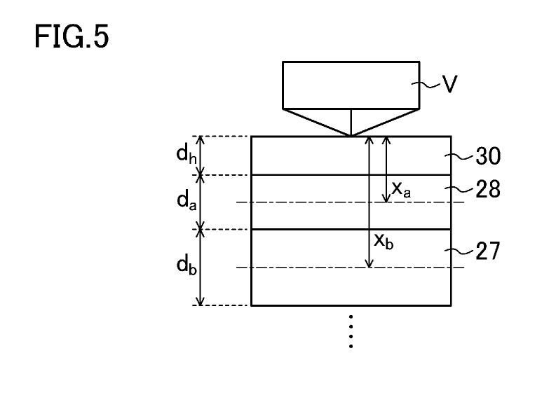

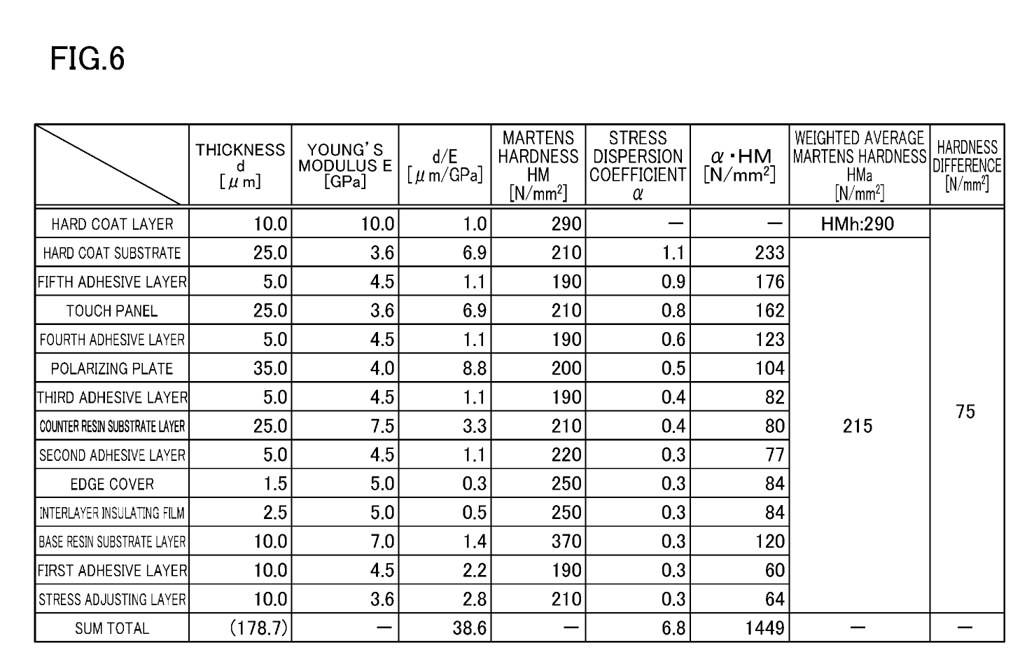

FIGS. 1 to 6 show an organic EL display device according to a first embodiment of the present invention. Here, FIG. 1 is a plan view showing a pixel structure of an organic EL display device 100a according to this embodiment. FIG. 2 is a cross-sectional view of the organic EL display device 100a taken along line II-II shown in FIG. 1. FIG. 3 is an equivalent circuit diagram of an organic EL element layer 20 forming part of the organic EL display device 100a. FIG. 4 is a cross-sectional view of an organic EL layer 17 forming part of the organic EL display device 100a. FIG. 5 is a schematic diagram for explaining the distance from a surface of a hard coat layer 30 of the organic EL display device 100a, where the distance is used to determine a stress dispersion coefficient α. FIG. 6 is a table showing specific information on an organic EL display device 100a which was fabricated as a first example.

As shown in FIG. 2, the organic EL display device 100a includes, for example, a base resin substrate layer 10 made of a polyimide resin, a stress adjusting layer 8 provided on a lower surface of the base resin substrate layer 10 in this drawing, an organic EL element layer 20 provided on an upper surface of the base resin substrate layer 10 in this drawing, an underlayer 29 provided on the organic EL element layer 20, and a hard coat layer 30 provided on the underlayer 29. Here, a display region (not shown) of the organic EL display device 100a includes a plurality of sub-pixels P arranged in a matrix as shown in FIG. 1. As shown in FIG. 1, some of the sub-pixels P in the display region of the organic EL display device 100a has a red light emission region Lr for displaying gradation of a red color, other ones of the sub-pixels P has a green light emission region Lg for displaying gradation of a green color, and still other ones of the sub-pixels P has a blue light emission region Lb for displaying gradation of a blue color. These sub-pixels P are adjacent to one another. Note that the display region of the organic EL display device 100a includes pixels each including three adjacent sub-pixels P having the red light emission region Lr, the green light emission region Lg, and the blue light emission region Lb, respectively.

The stress adjusting layer 8 is configured to control the position of a bending stress neutral plane of the organic EL display device 100a. Here, the stress adjusting layer 8 is configured as a plastic film made of, for example, polyethylene terephthalate, polyethylene naphthalate, aramid, (meth)acrylate, triacetylcellulose, or any other suitable material. A first adhesive layer 9 is provided between the base resin substrate layer 10 and the stress adjusting layer 8. The first adhesive layer 9 is, for example, a photo-curable adhesive sheet, a UV-curable adhesive, a thermoset adhesive, an epoxy adhesive, or a cyanoacrylate instant adhesive.

As shown in FIGS. 1 and 3, the organic EL element layer 20 includes a plurality of gate lines 11, a plurality of source lines 12a, and a plurality of power supply lines 12b. The gate lines 11 are provided on the base resin substrate layer 10 to extend parallel to one another in a lateral direction in these drawings. The source lines 12a are provided on the base resin substrate layer 10 to extend parallel to one another in a longitudinal direction in these drawings. The power supply lines 12b are provided on the base resin substrate layer 10 to be adjacent to the source lines 12a, respectively, and to extend parallel to one another in the longitudinal direction in these drawings. A moisture-proof layer is provided between the base resin substrate layer 10 and a gate layer forming the gate lines 11 and other lines. The moisture-proof layer is configured as a single-layer film, such as a silicon nitride film, a silicon oxide film, or a silicon oxynitride film, or a multilayer film of two or more of these films.

As shown in FIG. 3, the organic EL element layer 20 further includes a plurality of first thin film transistors (TFTs) 13a each provided for an associated one of the sub-pixels P, a plurality of second TFTs 13b each provided for an associated one of the sub-pixels P, and a plurality of capacitors 13c each provided for an associated one of the sub-pixels P. Here, each of the first TFTs 13a is connected to an associated one of the gate lines 11 and an associated one of the source lines 12a as shown in FIG. 3. Each of the second TFTs 13b is connected to an associated one of the first TFTs 13a and an associated one of the power supply lines 12b as shown in FIG. 3. The first TFTs 13a and the second TFTs 13b each include, for example, a gate electrode provided on the base resin substrate layer 10 with the moisture-proof layer interposed therebetween, a gate insulating film covering the gate electrode, a semiconductor layer provided on the gate insulating film to overlap with the gate electrode, and source and drain electrodes provided on the semiconductor layer to face each other. Each of the capacitors 13c is connected to an associated one of the first TFTs 13a and an associated one of the power supply lines 12b as shown in FIG. 3. The capacitors 13c each include, for example, two electrodes and a gate insulating film. One of the two electrodes is made of the same material as the gate lines 11, and is formed at the same level as the gate line 11. The other one of the two electrodes is made of the same material as the source lines 12a, and is formed at the same level as the source lines 12a. The gate insulating film is provided between a pair of these electrodes. Note that the first and second TFTs 13a and 13b configured as bottom gate TFTs in this embodiment may be configured as top gate TFTs.

As shown in FIG. 2, the organic EL element layer 20 further includes an interlayer insulating film 14, and a plurality of first electrodes 15 provided, as anodes, on the interlayer insulating film 14. The interlayer insulating film 14 substantially covers the first TFTs 13a (see FIG. 3), the second TFTs 13b, and the capacitors 13c (see FIG. 3). The first electrodes 15 are each provided for an associated one of the sub-pixels P, and are each connected to an associated one of the second TFTs 13b. Here, as shown in FIG. 2, the interlayer insulating film 14 covers each second TFT 13b, except for a portion of the drain electrode of the second TFT 13b. The interlayer insulation film 14 is made of, for example, a photosensitive acrylic resin, a photosensitive polyimide resin, a photosensitive polysiloxane resin, or any other suitable material. The first electrodes 15 are arranged in a matrix on the interlayer insulating film 14 such that each first electrode 15 corresponds to an associated one of the sub-pixels P. As shown in FIG. 2, the first electrode 15 of each sub-pixel P is connected to the drain electrode of an associated one of the second TFTs 13b via an associated one of contact holes formed in the interlayer insulating film 14. The first electrodes 15 function to inject holes (positive holes) into an organic EL layer 17 described below. To increase the efficiency in injecting positive holes into the organic EL layer 17, the first electrodes 15 are preferably made of a material having a high work function. Examples of materials for the first electrodes 15 include metal materials such as silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), and ytterbium (Yb). The first electrodes 15 may also be made of an alloy of, for example, magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), or lithium fluoride (LiF)/calcium (Ca)/aluminum (Al). Furthermore, the material for the first electrodes 15 may also be a conductive oxide such as tin oxide (SnO), zinc oxide (ZnO), indium tin oxide (ITO), and indium zinc oxide (IZO), for example. Moreover, the first electrodes 15 may be multilayers containing the above materials, such as ITO/Ag, IZO/Ag, and IZO/Al. Examples of the materials having a high work function, out of conductive oxides and other suitable materials, include indium tin oxide (ITO) and indium zinc oxide (IZO).

As shown in FIG. 2, the organic EL element layer 20 further includes an edge cover 16 formed in a grid pattern to cover peripheral portions of the first electrodes 15, and an organic EL layer 17 covering portions of the first electrodes 15 exposed from the edge cover 16. Examples of materials for the edge cover 16 include an inorganic film of silicon dioxide (SiO₂), silicon nitride (SiNx, where x is a positive number) such as Si₃N₄, and silicon oxynitride (SiNO), and an organic film of (photosensitive) polyimide resin, (photosensitive) acrylic resin, (photosensitive) polysiloxane resin, and novolak resin. As shown in FIG. 4, the organic EL layer 17 includes a positive hole injection layer 1, a positive hole transport layer 2, a light-emitting layer 3, an electron transport layer 4, and an electron injection layer 5, which are provided on the first electrodes 15 in this order.

The positive hole injection layer 1 is also called an anode buffer layer, and functions to bring the energy levels of the first electrodes 15 and the organic EL layer 17 closer to each other and increase efficiency in injection of positive holes from the first electrodes 15 into the organic EL layer 17. Here, examples of materials for the positive hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The positive hole transport layer 2 functions to increase efficiency in transportation of positive holes from the first electrodes 15 to the organic EL layer 17. Here, examples of materials for the positive hole transport layer 2 include porphyrin derivatives, aromatic tertiary amine compounds, styryl amine derivatives, polyvinylcarbazole, poly-p-phenylene vinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

When a voltage is applied from the first electrodes 15 and a second electrode 18 described below, positive holes and electrons are injected from the first and second electrodes 15 and 18 into the light-emitting layer 3, in which the positive holes and the electrons are recombined with each other. The light-emitting layer 3 is made of a material having high luminous efficiency. Examples of materials for the light-emitting layer 3 include metal oxinoid compounds (8-hydroxyquinoline metal complexes), naphthalene derivatives, anthracene derivatives, diphenylethylene derivatives, vinylacetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bis(styryl)benzene derivatives, tris(styryl)benzene derivatives, perylene derivatives, perinone derivatives, aminopyrene derivatives, pyridine derivatives, rodamine derivatives, acridine derivatives, phenoxazone, quinacridone derivatives, rubrene, poly-p-phenylene vinylene, and polysilane.

The electron transport layer 4 functions to efficiently move electrons to the light-emitting layer 3. Here, examples of materials for the electron transport layer 4 includes, as organic compounds, oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds.

The electron injection layer 5 functions to bring the energy levels of the second electrode 18 and the organic EL layer 17 closer to each other and increase efficiency in injection of electron from the second electrode 18 into the organic EL layer 17. This function contributes to reduction in the drive voltage of the organic EL element 20. The electron injection layer 5 may also be called a cathode buffer layer. Here, examples of materials for the electron injection layer 5 include inorganic alkaline compounds such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As shown in FIG. 2, the organic EL element layer 20 further includes the second electrode 18 provided as a cathode to cover the organic EL layer 17 and the edge cover 16, and a sealing film 19 covering the second electrode 18. Here, the second electrode 18 functions to inject electrons into the organic EL layers 17. To increase efficiency in injecting electrons into the organic EL layer 17, the second electrode 18 is preferably made of a material having a low work function. Examples of materials for the second electrode 18 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), and ytterbium (Yb). The second electrode 18 may also be made of, for example, an alloy of magnesium (Mg)/copper (Cu), magnesium (Mg)/silver (Ag), sodium (Na)/potassium (K), astatine (At)/astatine dioxide (AtO₂), lithium (Li)/aluminum (Al), lithium (Li)/calcium (Ca)/aluminum (Al), and lithium fluoride (LiF)/calcium (Ca)/aluminum (Al). The second electrode 18 may also be made of, for example, a conductive oxide such as tin oxide (SnO), zinc oxide (ZnO), indium tin oxide (ITO), and indium zinc oxide (IZO). Moreover, the second electrode 18 may be multilayers containing the above materials, such as ITO/Ag. Examples of materials having a low work function include magnesium (Mg), lithium (Li), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al). The sealing film 19 functions to protect the organic EL layer 17 against moisture and oxygen. Examples of materials for the sealing film 19 include inorganic materials such as silicon dioxide (SiO₂), aluminum oxide (Al₂O₃), silicon nitride (SiNx, where x is a positive number) such as Si₃N₄, and silicon carbonitride (SiCN), and organic materials such as acrylate, polyurea, parylene, polyimide, and polyamide.

The underlayer 29 includes a second adhesive layer 21, a counter resin substrate layer 22, a third adhesive layer 23, a polarizing plate 24, a fourth adhesive layer 25, a touch panel 26, a fifth adhesive layer 27, and a hard coat substrate 28, which are provided on the sealing film 19 in this order as shown in FIG. 2.

The second adhesive layer 21 is, for example, a UV post curable adhesive, a thermoset adhesive, an epoxy adhesive, an acrylic adhesive, or a polyolefin adhesive.

The counter resin substrate layer 22 is configured as a plastic film made of, for example, polyimide, polyethylene terephthalate, polyethylene naphthalate, aramid, or (meth)acrylate.

Each of the third, fourth, and fifth adhesive layers 23, 25, and 27 is made of, for example, a photo-curable adhesive sheet, a UV curable adhesive, a thermoset adhesive, an epoxy adhesive, or a cyanoacrylate instant adhesive.

The polarizing plate 24 includes a polarizer layer obtained by uniaxially stretching a polyvinyl alcohol film that has adsorbed iodine, and a pair of protective films sandwiching the polarizer layer, and contains, as the main ingredient, triacetylcellulose forming the pair of the protective films.

The touch panel 26 includes, for example, a base film, and a capacitive touch panel layer provided on the base film, and contains, as the main ingredient, a plastic film forming the base film. The plastic film is made of polyimide, polyethylene terephthalate, polyethylene naphthalate, aramid, (meth)acrylate, or any other suitable material. Here, the touch panel layer includes a metal interconnect forming a grid pattern by patterning to detect a touched portion of the touch panel. However, the amount of plastic deformation is calculated without reflecting the touch panel layer, because the metal interconnect has a high Young's modulus, and has a small thickness of 1 μm or less.

The hard coat substrate 28 is configured as a plastic film made of, for example, polyimide, polyethylene terephthalate, polyethylene naphthalate, aramid, or (meth)acrylate.

The hard coat layer 30 is made of, for example, a UV curable organosilicon resin, a thermoset resin, an acrylic resin, an urethane resin, or a polysiloxane resin.

The organic EL display device 100a having the configuration is configured as follows. Specifically, in each of the sub-pixels P, a gate signal is input through the gate line 11 to the first TFT 13a to turn the first TFT 13a on, a predetermined voltage corresponding to a source signal is written through the source line 12a into the gate electrode of the second TFT 13b and the capacitor 13c, and the magnitude of a current from the power supply line 12b is determined based on the gate voltage of the second TFT 13b. The determined current is supplied to the light-emitting layer 3 so that the light-emitting layer 3 emits light, thereby displaying an image. In the organic EL display device 100a, even if the first TFT 13a is turned off, the gate voltage of the second TFT 13b is retained by the capacitor 13c. Thus, the light-emitting layer 3 keeps emitting light until the first TFT 13a receives a gate signal in a subsequent frame.

The organic EL display device 100a according to this embodiment can be fabricated, for example, in the following manner. Specifically, an organic EL element layer 20 is formed, by a known method, on a surface of a base resin substrate layer 10 formed on a glass substrate, an underlayer 29 and a hard coat layer 30 are stacked on the organic EL element layer 20, and then a first adhesive layer 9 and a stress adjusting layer 8 are formed on the back surface of the base resin substrate layer 10 from which the glass substrate has been separated. Note that in the organic EL display device 100a, the stress adjusting layer 8, the first adhesive layer 9, the base resin substrate layer 10, the organic EL element layer 20, and the underlayer 29 form a stack layer Sa as shown in FIG. 2.

The organic EL display device 100a according to this embodiment is configured such that the difference between the Martens hardness HMh of the hard coat layer 30 alone and the weighted average Martens hardness HMa of the components of the stack layer Sa by the stress dispersion coefficients α of the components is less than or equal to 79 N/mm². If the difference between the Martens hardness HMh of the hard coat layer 30 alone and the weighted average Martens hardness HMa of the components of the stack layer Sa by their stress dispersion coefficients α exceeds 79 N/mm², a semipermanent plastic deformation (flaw) on a surface of the hard coat layer 30 tends to be visually identified.

The Martens hardnesses HM of the components are determined by F/(26.43 h²), where h is a maximum indentation depth (mm) to which a Vickers indenter V (see FIG. 5) can be pressed against each component by nanoindentation (ISO 14577) under a load F of 3 mN to 6 mN (in each of examples and comparative examples described below, F=4 mN). The Young's modulus E of each component, described below, is determined by the indentation elasticity modulus thereof measured by nanoindentation.

The stress dispersion coefficient α of each component for use to obtain the weighted average Martens hardness is determined by the following formulae:

α=−1.5×10⁻⁷x³+8.6×10⁻⁵x²−1.7×10⁻²x+1.45

where x is the distance (μm) from a surface (an upper surface) of the hard coat layer 30 remote from the underlayer 29 to the centerline of the component orthogonal to the thickness direction, and is less than or equal to 300; and

α=0

where x is greater than 300. The distance x from the upper surface of the hard coat layer 30 having a thickness dₕ to the centerline of the component orthogonal to the thickness direction will now be described with reference to FIG. 5, for example. The distance xₐ therefrom to the centerline of the hard coat substrate 28 with a thickness dₐ is equal to dₕ+dₐ/2. The distance x_{b} therefrom to the centerline of the fifth adhesive layer 27 with a thickness db is equal to dₕ+dₐ+dₕ/2.

The thickness d, Young's modulus E, Martens hardness HM, and stress dispersion coefficient α of each of components of a structure including a stack, such as the organic EL element layer 20 or the underlayer 29, are determined. The determined Martens hardnesses HM and the determined stress dispersion coefficients α are appropriately substituted into the following formula for calculating the weighted average Martens hardness, based on the magnitude of the ratio d/E of the thickness d to the Young's modulus E.

HMa=(α₁HM₁+α₂HM₂+ . . . +α_{c}HMₙ)/(α₁+α₂+ . . . +αₙ)

Next, an experiment which was actually conducted will be described.

An organic EL display device 100a configured as indicated below was fabricated as an example of this embodiment (a first example) (see the table shown in FIG. 6). The names and other features of materials described below are the names and other features of corresponding materials used to determine their actual thicknesses d, Young's moduli E, Martens hardnesses HM, and stress dispersion coefficients α.

Stress Adjusting Layer 8: a polyethylene terephthalate film with a thickness of 10.0 μm
First Adhesive Layer 9: an epoxy resin adhesive with a thickness of 10.0 μm (made by Alteco Co., Ltd.)
Base Resin Substrate Layer 10: a non-photosensitive polyimide resin coating with a thickness of 10.0 μm (PIQ (registered trademark) series made by Hitachi Chemical DuPont Microsystems Ltd)
Moisture-Proof Layer: a silicon nitride film with a thickness of 1.0 μm, formed by plasma CVD (chemical vapor deposition) (Young's modulus: 240.0 GPa)
First TFT 13a and Other Transistors: A configuration for a typical bottom gate TFT with a total thickness of 0.3 μm, which includes a wiring layer configured as a Ti/Al/Ti or Al/Ti multilayer film (Young's modulus: 200.0 GPa)
Interlayer Insulating Film 14: a photosensitive acrylic resin with a thickness of 2.5 μm (Optomer (registered trademark) series made by JSR Corporation)
First Electrode 15: an ITO/Ag multilayer film with a thickness of 0.1 μm, formed by a typical TFT process (Young's modulus: 200.0 GPa)
Edge Cover 16: a photosensitive acrylic resin with a thickness of 1.5 μm (Optomer (registered trademark) series made by JSR Corporation)
Organic EL Layer 17: a configuration of a typical organic EL element with a total thickness of 0.2 μm (Young's modulus: 2.0 GPa)
Second Electrode 18: an Ag film with a thickness of 0.1 μm, formed by an evaporation method (Young's modulus: 200.0 GPa)
Sealing Film 19: a silicon nitride film with a thickness of 3.0 μm, formed by low-temperature plasma CVD (Young's modulus: 80.0 GPa)
Second Adhesive Layer 21: a UV post curable adhesive with a thickness of 5.0 μm (Photorec (registered trademark) E series made by SEKISUI CHEMICAL CO., LTD.)
Counter Resin Substrate Layer 22: an aramid film with a thickness of 25.0 μm Third Adhesive Layer 23: an epoxy resin adhesive with a thickness of 5.0 μm (made by Alteco Co., Ltd.)
Polarizing Plate 24: triacetylcellulose with a thickness of 35.0 μm
Fourth Adhesive Layer 25: an epoxy resin adhesive with a thickness of 5.0 μm (made by Alteco Co., Ltd.)
Touch Panel 26: a polyethylene terephthalate film with a thickness of 25.0 μm
Fifth Adhesive Layer 27: an epoxy resin adhesive with a thickness of 5.0 μm (made by Alteco Co., Ltd.)
Hard Coat Substrate 28: a polyethylene terephthalate film with a thickness of 25.0 μm
Hard Coat Layer 30: a UV curable organosilicon resin with a thickness of 10.0 μm
   Here, the Martens hardnesses HM and the indentation elasticity moduli of the films and coatings were measured by nanoindentation with each of the films with a thickness of 10 μm or more bonded onto a glass substrate and with each of the coatings with a thickness of 10 μm or more formed on a glass substrate. The ratio d/E of each of the moisture-proof layer, the first TFT 13a, other transistors, the first electrode 15, the organic EL layer 17, the second electrode 18, and the sealing film 19 forming the organic EL element layer 20 is less than or equal to 1/100 of the sum total of these ratios d/E (38.8 μm/GPa). Thus, these ratios are omitted from the table shown in FIG. 6, and the weighted average Martens hardness HMa was calculated without reflecting these ratios.

In the fabricated organic EL display device 100a, the difference between the Martens hardness HMh of the hard coat layer 30 alone and the weighted average Martens hardness HMa of the components of the stack layer Sa was 75 N/mm² as shown in the table in FIG. 6. Even after the upper surface of the hard coat layer 30 was pressed under a high pressure (e.g., 90 MPa), a semipermanent plastic deformation (flaw) on the device surface (the surface of the hard coat layer 30) was hardly visually identified.

As can be seen from the foregoing description, the organic EL display device 100a of this embodiment can provide the following advantages.

The difference between the Martens hardness HMh of the hard coat layer 30 alone and the weighted average Martens hardness HMa of the components of the stack layer Sa, which includes the base resin substrate layer 10, the organic EL element layer 20, and the underlayer 29, by the stress dispersion coefficients α of the components is less than or equal to 79 N/mm². This can reduce the plastic deformation of the hard coat layer 30 forming a surface of the organic EL display device 100a. This reduces the degree to which the reflection of natural light entering a display screen of the organic EL display device 100a or light emitted from the organic EL element layer 20 scatters in the surface of the hard coat layer 30. Thus, the display quality of the organic EL display device 100a can be maintained.

### Second Embodiment

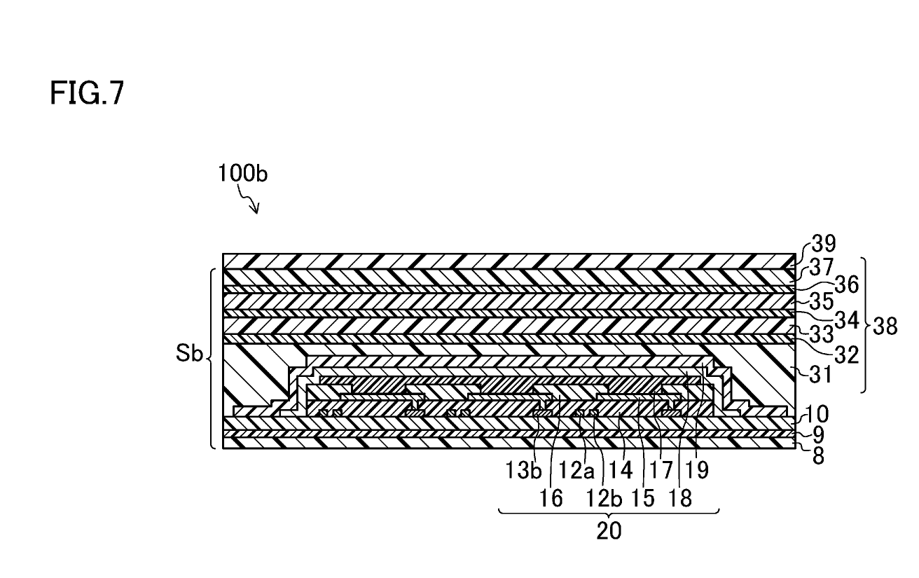

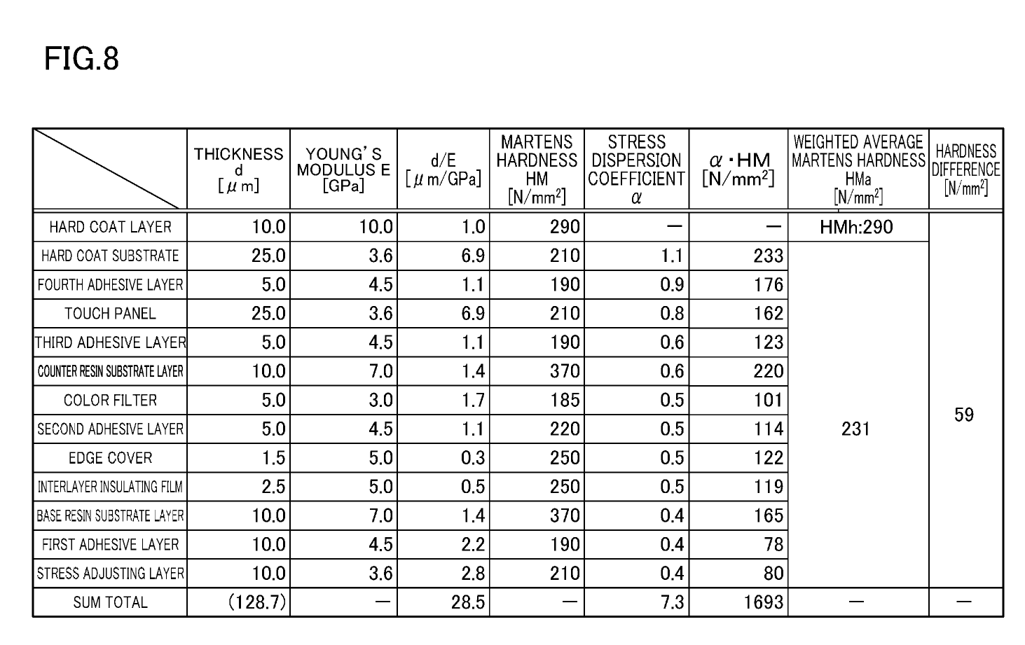

FIGS. 7 and 8 show an organic EL display device according to a second embodiment of the present invention. Here, FIG. 7 is a cross-sectional view of an organic EL display device 100b according to this embodiment. FIG. 8 is a table showing specific information on an organic EL display device 100b fabricated as a second example. In the embodiments below, components equivalent to those shown in FIGS. 1 to 6 are denoted by the same reference characters, and the detailed explanation thereof will be omitted.

In the first embodiment, the organic EL display device 100a including the polarizing plate 24 has been exemplified. On the other hand, in this embodiment, an organic EL display device 100b including a color filter 32 instead of the polarizing plate 24 is exemplified.

As shown in FIG. 7, the organic EL display device 100b includes a base resin substrate layer 10, a stress adjusting layer 8 provided on a lower surface of the base resin substrate layer 10 in this drawing, an organic EL element layer 20 provided on an upper surface of the base resin substrate layer 10 in this drawing, an underlayer 38 provided on the organic EL element layer 20, and a hard coat layer 39 provided on the underlayer 38. Note that the structure of each of pixels arranged in a display region of the organic EL display device 100b is substantially the same as that of each of the pixels arranged in a display region of the organic EL display device 100a of the first embodiment.

The underlayer 38 includes a second adhesive layer 31, a color filter 32, a counter resin substrate layer 33, a third adhesive layer 34, a touch panel 35, a fourth adhesive layer 36, and a hard coat substrate 37, which are provided on the sealing film 19 in this order as shown in FIG. 7.

The second adhesive layer 31 is, for example, a UV post curable adhesive, a thermoset adhesive, an epoxy adhesive, an acrylic adhesive, or a polyolefin adhesive.

The color filter 32 includes, for example, a black matrix layer formed in a grid pattern, a plurality of color resist layers, such as a red layer, a green layer, and a blue layer, each corresponding to one of sub-pixels P, and an overcoat layer covering the black matrix layer and the color resist layers, and contains, as the main ingredient, a photosensitive acrylic resin, a photosensitive polyimide resin, a photosensitive polysiloxane resin, or any other suitable material. The color filter 32 is formed on the counter resin substrate layer 33.

The counter resin substrate layer 33 is configured as a plastic film made of, for example, polyimide, polyethylene terephthalate, polyethylene naphthalate, aramid, or (meth)acrylate.

The third and fourth adhesive layers 34 and 36 are made of, for example, a photo-curable adhesive sheet, a UV curable adhesive, a thermoset adhesive, an epoxy adhesive, or a cyanoacrylate instant adhesive.

The touch panel 35 includes, for example, a base film, and a capacitive touch panel layer provided on the base film, and contains, as the main ingredient, a plastic film forming the base film. The plastic film is made of polyimide, polyethylene terephthalate, polyethylene naphthalate, aramid, (meth)acrylate, or any other suitable material.

The hard coat substrate 37 is configured as a plastic film made of, for example, polyimide, polyethylene terephthalate, polyethylene naphthalate, aramid, or (meth)acrylate.

The hard coat layer 39 is made of, for example, a UV curable organosilicon resin, a thermoset resin, an acrylic resin, an urethane resin, or a polysiloxane resin.

Just like the organic EL display device 100a of the first embodiment, the organic EL display device 100b having the configuration displays an image when a light-emitting layer 3 appropriately emits light in each of the sub-pixels P. The organic EL display device 100a of the first embodiment does not include a color filter (32), and thus includes a light-emitting layer 3 emitting light with three colors, i.e., RGB. A region of the light-emitting layer 3 corresponding to each of the sub-pixels P emits light with one of the three colors. However, since the organic EL display device 100b of this embodiment includes the color filter 32, the organic EL display device 100b includes a light-emitting layer 3 emitting white light in all of the sub-pixels P.

The organic EL display device 100b of this embodiment can be fabricated through appropriate modification of the method for fabricating the organic EL display device 100a of the first embodiment. Note that in the organic EL display device 100b, the stress adjusting layer 8, the first adhesive layer 9, the base resin substrate layer 10, the organic EL element layer 20, and the underlayer 38 form a stack layer Sb as shown in FIG. 7.

The organic EL display device 100b according to this embodiment is configured such that the difference between the Martens hardness HMh of the hard coat layer 39 alone and the weighted average Martens hardness HMa of the components of the stack layer Sb by the stress dispersion coefficients α of the components is less than or equal to 79 N/mm². If the difference between the Martens hardness HMh of the hard coat layer 39 alone and the weighted average Martens hardness HMa of the components of the stack layer Sb by the stress dispersion coefficients α exceeds 79 N/mm², a semipermanent plastic deformation (flaw) on a surface of the hard coat layer 39 tends to be visually identified.

The stress dispersion coefficient α of each component for use to calculate the weighted average Martens hardness is determined by the following formulae.

α=−1.5×10⁻⁷x³+8.6×10⁻⁵x²−1.7×10⁻²x+1.45

where x is the distance (μm) from a surface (an upper surface) of the hard coat layer 39 remote from the underlayer 38 to the centerline of the component orthogonal to the thickness direction, and is less than or equal to 300; and

α=0

where x is greater than 300.

The thickness d, Young's modulus E, Martens hardness HM, and stress dispersion coefficient α of each of components of a structure including a stack, such as the organic EL element layer 20 or the underlayer 38, are determined. The determined Martens hardness HM and stress dispersion coefficient α are appropriately substituted into the following formula for calculating the weighted average Martens hardness, based on the magnitude of the ratio d/E of the thickness d to the Young's modulus E.

HMa=(α₁HM₁+α₂HM₂+ . . . +αₙHMₙ)/(α₁+α₂+ . . . +αₙ)

Next, an experiment which was actually conducted will be described.

An organic EL display device 100b configured as indicated below was fabricated as an example of this embodiment (a second example) (see the table shown in FIG. 8). The names and other features of materials described below are the names and other features of corresponding materials used to determine their actual thicknesses d, Young's moduli E, Martens hardnesses HM, and stress dispersion coefficients α.

Stress Adjusting Layer 8: a polyethylene terephthalate film with a thickness of 10.0 μm
First Adhesive Layer 9: an epoxy resin adhesive with a thickness of 10.0 μm (made by Alteco Co., Ltd.)
Base Resin Substrate Layer 10: a non-photosensitive polyimide resin coating with a thickness of 10.0 μm (PIQ (registered trademark) series made by Hitachi Chemical DuPont Microsystems Ltd)
Moisture-Proof Layer: a silicon nitride film with a thickness of 1.0 μm, formed by plasma CVD (chemical vapor deposition) (Young's modulus: 240.0 GPa)
First TFT 13a and Other Transistors: A configuration for a typical bottom gate TFT with a total thickness of 0.3 μm, which includes a wiring layer configured as a Ti/Al/Ti or Al/Ti multilayer film (Young's modulus: 200.0 GPa)
Interlayer Insulating Film 14: a photosensitive acrylic resin with a thickness of 2.5 μm (Optomer (registered trademark) series made by JSR Corporation)
First Electrode 15: an ITO/Ag multilayer film with a thickness of 0.1 μm, formed by a typical TFT process (Young's modulus: 200.0 GPa)
Edge Cover 16: a photosensitive acrylic resin with a thickness of 1.5 μm (Optomer (registered trademark) series made by JSR Corporation)
Organic EL Layer 17: a configuration of a typical organic EL element with a total thickness of 0.2 μm (Young's modulus: 2.0 GPa)
Second Electrode 18: an Ag film with a thickness of 0.1 μm, formed by an evaporation method (Young's modulus: 200.0 GPa)
Sealing Film 19: a silicon nitride film with a thickness of 3.0 μm, formed by low-temperature plasma CVD (Young's modulus: 80.0 GPa)
Second Adhesive Layer 31: a UV post curable adhesive with a thickness of 15.0 μm (Photorec (registered trademark) E series made by SEKISUI CHEMICAL CO., LTD.)
Color Filter 32: a photosensitive color filter resin with a thickness of 5.0 μm (COLOR MOSAIC (registered trademark) series made by Fujifilm Corporation)
Counter Resin Substrate Layer 33: a non-photosensitive polyimide resin coating with a thickness of 10.0 μm (PIQ (registered trademark) series made by Hitachi Chemical DuPont Microsystems Ltd)
Third Adhesive Layer 34: an epoxy resin adhesive with a thickness of 5.0 μm (made by Alteco Co., Ltd.)
Touch Panel 35: a polyethylene terephthalate film with a thickness of 25.0 μm
Fourth Adhesive Layer 36: an epoxy resin adhesive with a thickness of 5.0 μm (made by Alteco Co., Ltd.)
Hard Coat Substrate 37: a polyethylene terephthalate film with a thickness of 25.0 μm Hard Coat Layer 39: a UV curable organosilicon resin with a thickness of 10.0 μm
   The ratio d/E of each of the moisture-proof layer, the first TFT 13a, other transistors, the first electrode 15, the organic EL layer 17, the second electrode 18, and the sealing film 19 forming the organic EL element layer 20 is less than or equal to 1/100 of the sum total of these ratios d/E (28.7 μm/GPa). Thus, these ratios are omitted from the table shown in FIG. 8, and the weighted average Martens hardness HMa was calculated without reflecting these ratios.

In the fabricated organic EL display device 100b, the difference between the Martens hardness HMh of the hard coat layer 39 alone and the weighted average Martens hardness HMa of the components of the stack layer Sb was 59 N/mm² as shown in the table in FIG. 8. Even after the upper surface of the hard coat layer 39 was pressed under a high pressure (e.g., 90 MPa), a semipermanent plastic deformation (flaw) on the device surface (the surface of the hard coat layer 39) was hardly visually identified.

As can be seen, the organic EL display device 100b of this embodiment can provide the following advantages.

The difference between the Martens hardness HMh of the hard coat layer 39 alone and the weighted average Martens hardness HMa of the components of the stack layer Sb, which includes the base resin substrate layer 10, the organic EL element layer 20, and the underlayer 38, by the stress dispersion coefficients α of the components is less than or equal to 79 N/mm². This can reduce plastic deformation of the hard coat layer 39 forming the surface of the organic EL display device 100b. This reduces the degree to which the reflection of natural light entering a display screen of the organic EL display device 100b or light emitted from the organic EL element layer 20 scatters in the surface of the hard coat layer 39. Thus, the display quality of the organic EL display device 100b can be maintained.

### Third Embodiment

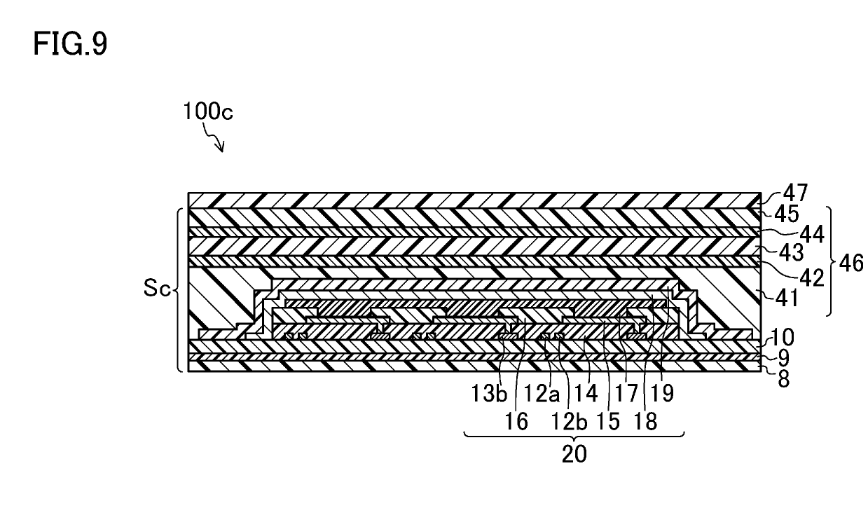

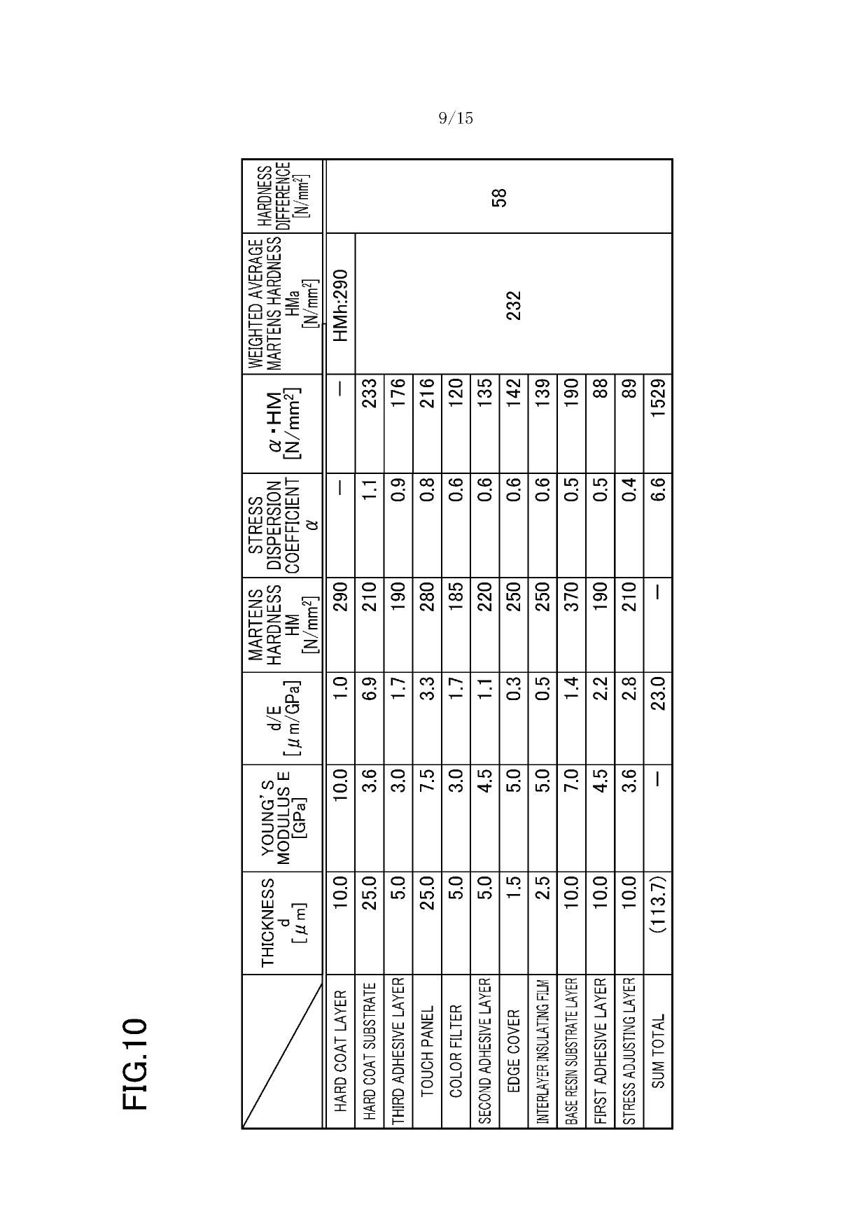

FIGS. 9 and 10 show an organic EL display device according to a third embodiment of the present invention. Here, FIG. 9 is a cross-sectional view of an organic EL display device 100c according to this embodiment. FIG. 10 is a table showing specific information on the organic EL display device 100c fabricated as a third example.

In the first and second embodiments, the organic EL display devices 100a and 100b including the counter resin substrate layers 22 and 33, respectively, have been exemplified. On the other hand, in this embodiment, the organic EL display device 100c that does not include a counter resin substrate layer is exemplified.

As shown in FIG. 9, the organic EL display device 100c includes a base resin substrate layer 10, a stress adjusting layer 8 provided on a lower surface of the base resin substrate layer 10 in this drawing, an organic EL element layer 20 provided on an upper surface of the base resin substrate layer 10 in this drawing, an underlayer 46 provided on the organic EL element layer 20, and a hard coat layer 47 provided on the underlayer 46. Note that the structure of each of pixels arranged in a display region of the organic EL display device 100c is substantially the same as that of each of the pixels arranged in a display region of the organic EL display device 100a of the first embodiment.

The underlayer 46 includes a second adhesive layer 41, a color filter 42, a touch panel 43, a third adhesive layer 44, and a hard coat substrate 45, which are provided on the sealing film 19 in this order as shown in FIG. 9.

The second adhesive layer 41 is, for example, a UV post curable adhesive, a thermoset adhesive, an epoxy adhesive, an acrylic adhesive, or a polyolefin adhesive.

The color filter 42 includes, for example, a black matrix layer formed in a grid pattern, a plurality of color resist layers, such as a red layer, a green layer, and a blue layer, each corresponding to one of the sub-pixels P, and an overcoat layer covering the black matrix layer and the color resist layers, and contains, as the main ingredient, a photosensitive acrylic resin, a photosensitive polyimide resin, a photosensitive polysiloxane resin, or any other suitable material. The color filter 42 is formed on the touch panel 43.

The touch panel 43 includes, for example, a base film, and a capacitive touch panel layer provided on the base film, and contains, as the main ingredient, a plastic film forming the base film. The plastic film is made of polyimide, polyethylene terephthalate, polyethylene naphthalate, aramid, (meth)acrylate, or any other suitable material.

The third adhesive layer 44 is made of, for example, a photo-curable adhesive sheet, a UV curable adhesive, a thermoset adhesive, an epoxy adhesive, or a cyanoacrylate instant adhesive.

The hard coat substrate 45 is configured as a plastic film made of, for example, polyimide, polyethylene terephthalate, polyethylene naphthalate, aramid, or (meth)acrylate.

The hard coat layer 47 is made of, for example, a UV curable organosilicon resin, a thermoset resin, an acrylic resin, an urethane resin, or a polysiloxane resin.

Just like the organic EL display device 100a of the first embodiment, the organic EL display device 100c configured as described above displays an image when the light-emitting layer 3 appropriately emits light in each of the sub-pixels P.

The organic EL display device 100c of this embodiment can be fabricated through appropriate modification of the method for fabricating the organic EL display device 100a of the first embodiment. Note that in the organic EL display device 100c, the stress adjusting layer 8, the first adhesive layer 9, the base resin substrate layer 10, the organic EL element layer 20, and the underlayer 46 form a stack layer Sc as shown in FIG. 9.

The organic EL display device 100c according to this embodiment is configured such that the difference between the Martens hardness HMh of the hard coat layer 47 alone and the weighted average Martens hardness HMa of the components of the stack layer Sc by the stress dispersion coefficients α of the components is less than or equal to 79 N/mm². If the difference between the Martens hardness HMh of the hard coat layer 47 alone and the weighted average Martens hardness HMa of the components of the stack layer Sc by the stress dispersion coefficients α exceeds 79 N/mm², a semipermanent plastic deformation (flaw) on a surface of the hard coat layer 47 tends to be visually identified.

The stress dispersion coefficient α of each component for use to calculate the weighted average Martens hardness is determined by the following formulae.

α=−1.5×10⁻⁷x³+8.6×10⁻⁵x²−1.7×10⁻²x+1.45

where x is the distance (μm) from a surface (an upper surface) of the hard coat layer 47 remote from the underlayer 46 to the centerline of the component orthogonal to the thickness direction, and is less than or equal to 300; and

α=0

where x is greater than 300.

The thickness d, Young's modulus E, Martens hardness HM, and stress dispersion coefficient α of each of components of a structure including a stack, such as the organic EL element layer 20 or the underlayer 46, are determined. The determined Martens hardness HM and stress dispersion coefficient α are appropriately substituted into the following formula for calculating the weighted average Martens hardness, based on the magnitude of the ratio d/E of the thickness d to the Young's modulus E.

HMa=(α₁HM₁+α₂HM₂+ . . . +αₙHMₙn)/(α₁+α₂+ . . . +αₙ)

Next, an experiment which was actually conducted will be described.

An organic EL display device 100c configured as indicated below was fabricated as an example of this embodiment (a third example) (see the table shown in FIG. 10). The names and other features of materials described below are the names and other features of corresponding materials used to determine their actual thicknesses d, Young's moduli E, Martens hardnesses HM, and stress dispersion coefficients α.

Stress Adjusting Layer 8: a polyethylene terephthalate film with a thickness of 10.0 μm
First Adhesive Layer 9: an epoxy resin adhesive with a thickness of 10.0 μm (made by Alteco Co., Ltd.)
Base Resin Substrate Layer 10: a non-photosensitive polyimide resin coating with a thickness of 10.0 μm (PIQ (registered trademark) series made by Hitachi Chemical DuPont Microsystems Ltd)
Moisture-Proof Layer: a silicon nitride film with a thickness of 1.0 μm, formed by plasma CVD (chemical vapor deposition) (Young's modulus: 240.0 GPa)
First TFT 13a and Other Transistors: A configuration for a typical bottom gate TFT with a total thickness of 0.3 μm, which includes a wiring layer configured as a Ti/Al/Ti or Al/Ti multilayer film (Young's modulus: 200.0 GPa)
Interlayer Insulating Film 14: a photosensitive acrylic resin with a thickness of 2.5 μm (Optomer (registered trademark) series made by JSR Corporation)
First Electrode 15: an ITO/Ag multilayer film with a thickness of 0.1 μm, formed by a typical TFT process (Young's modulus: 200.0 GPa)
Edge Cover 16: a photosensitive acrylic resin with a thickness of 1.5 μm (Optomer (registered trademark) series made by JSR Corporation)
Organic EL Layer 17: a configuration of a typical organic EL element with a total thickness of 0.2 μm (Young's modulus: 2.0 GPa)
Second Electrode 18: an Ag film with a thickness of 0.1 μm, formed by an evaporation method (Young's modulus: 200.0 GPa)
Sealing Film 19: a silicon nitride film with a thickness of 3.0 μm, formed by low-temperature plasma CVD (Young's modulus: 80.0 GPa)
Second Adhesive Layer 41: a UV post curable adhesive with a thickness of 5.0 μm (Photorec (registered trademark) E series made by SEKISUI CHEMICAL CO., LTD.)
Color Filter 42: a photosensitive color filter resin with a thickness of 5.0 μm (COLOR MOSAIC (registered trademark) series made by Fujifilm Corporation)
Touch Panel 43: an aramid film with a thickness of 25.0 μm
Third Adhesive Layer 44: an epoxy resin adhesive with a thickness of 5.0 μm (made by Alteco Co., Ltd.)
Hard Coat Substrate 45: a polyethylene terephthalate film with a thickness of 25.0 μm
Hard Coat Layer 47: a UV curable organosilicon resin with a thickness of 10.0 μm
   The ratio d/E of each of the moisture-proof layer, the first TFT 13a, other transistors, the first electrode 15, the organic EL layer 17, the second electrode 18, and the sealing film 19 forming the organic EL element layer 20 is less than or equal to 1/100 of the sum total of these ratios d/E (23.1 μ/GPa). Thus, these ratios are omitted from the table shown in FIG. 10, and the weighted average Martens hardness HMa was calculated without reflecting these ratios.

In the fabricated organic EL display device 100c, the difference between the Martens hardness HMh of the hard coat layer 47 alone and the weighted average Martens hardness HMa of the components of the stack layer Sc was 58 N/mm² as shown in the table in FIG. 10. Even after the upper surface of the hard coat layer 47 was pressed under a high pressure (e.g., 90 MPa), a semipermanent plastic deformation (flaw) on the device surface (the surface of the hard coat layer 47) was hardly visually identified.

As can be seen, the organic EL display device 100c of this embodiment can provide the following advantages.

The difference between the Martens hardness HMh of the hard coat layer 47 alone and the weighted average Martens hardness HMa of the components of the stack layer Sc, which includes the base resin substrate layer 10, the organic EL element layer 20, and the underlayer 46, by the stress dispersion coefficients α of the components is less than or equal to 79 N/mm². This can reduce plastic deformation of the hard coat layer 47 forming the surface of the organic EL display device 100c. This reduces the degree to which the reflection of natural light entering a display screen of the organic EL display device 100c or light emitted from the organic EL element layer 20 scatters in the surface of the hard coat layer 47. Thus, the display quality of the organic EL display device 100c can be maintained.

In the organic EL display device 100c, the touch panel 43 serves also as the counter resin substrate layers 22 and 33 of the first and second embodiments. This can reduce the thickness of the organic EL display device 100c, the costs of components, and manufacturing cost.

### Fourth Embodiment

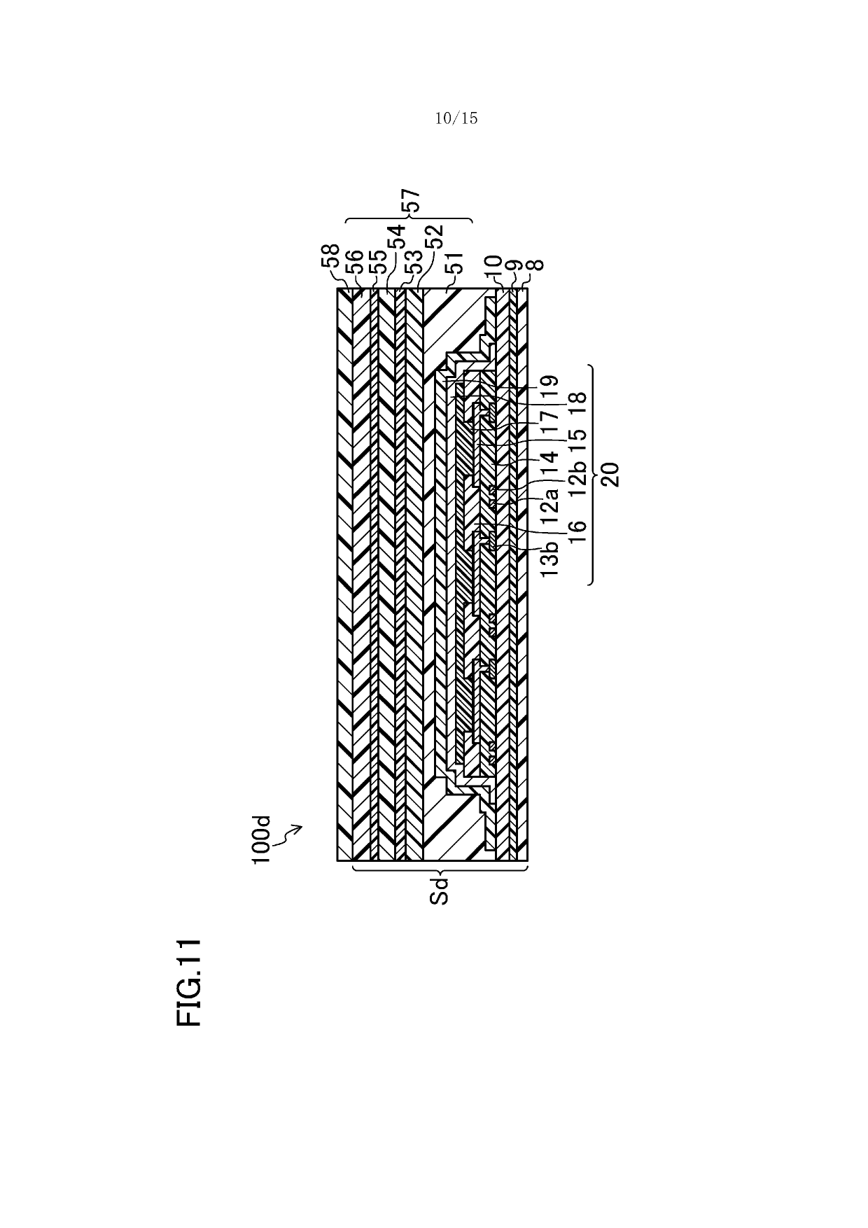

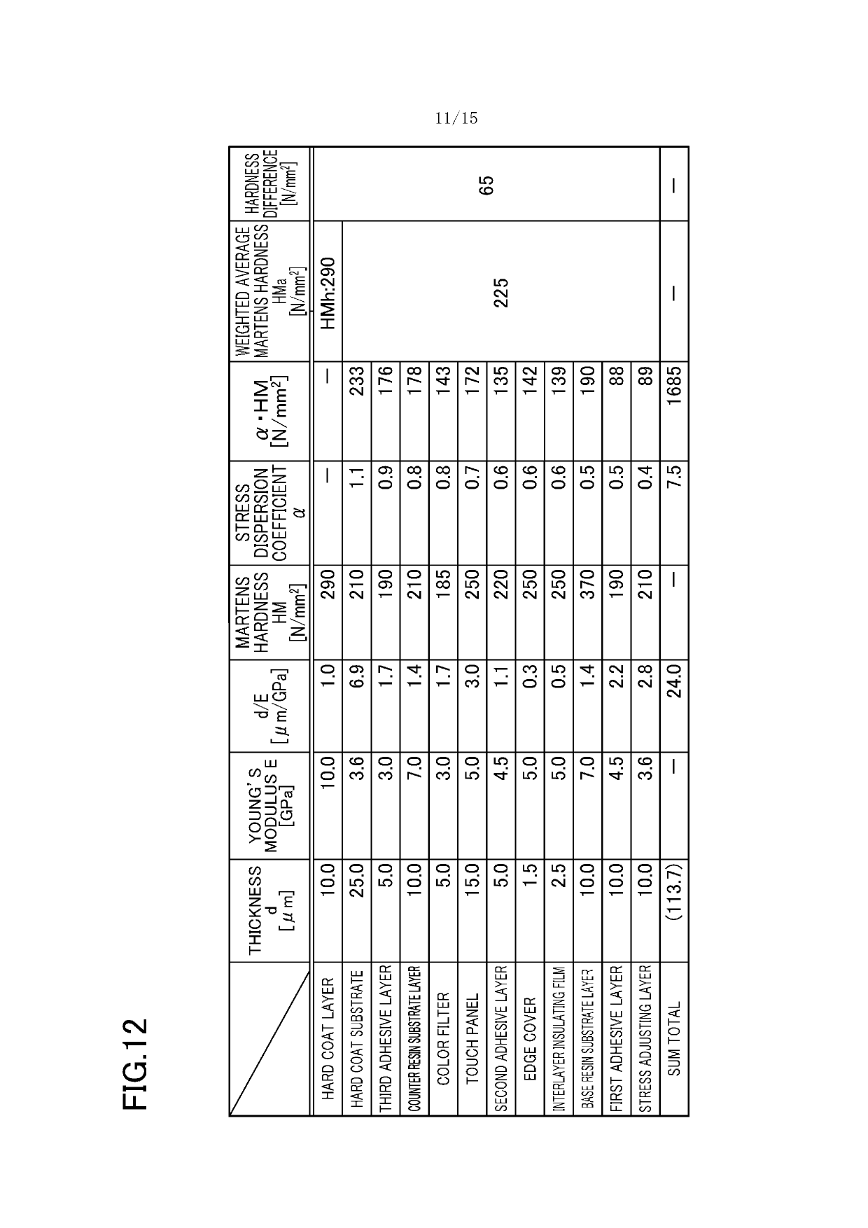

FIGS. 11 and 12 show an organic EL display device according to a fourth embodiment of the present invention. Here, FIG. 11 is a cross-sectional view of an organic EL display device 100d according to this embodiment. FIG. 12 is a table showing specific information on the organic EL display device 100d fabricated as a fourth example.

In the second embodiment, the organic EL display device 100b including the touch panel 35 provided on a side of the counter resin substrate layer 33 remote from the resin substrate layer 10 has been exemplified. On the other hand, in this embodiment, the organic EL display device 100d including a touch panel 52 provided between a base resin substrate layer 10 and a counter resin substrate layer 54 is exemplified.

As shown in FIG. 11, the organic EL display device 100d includes the base resin substrate layer 10, a stress adjusting layer 8 provided on a lower surface of the base resin substrate layer 10 in this drawing, an organic EL element layer 20 provided on an upper surface of the base resin substrate layer 10 in this drawing, an underlayer 57 provided on the organic EL element layer 20, and a hard coat layer 58 provided on the underlayer 57. Note that the structure of each of pixels arranged in a display region of the organic EL display device 100d is substantially the same as that of each of the pixels arranged in a display region of the organic EL display device 100a of the first embodiment.

The underlayer 57 includes a second adhesive layer 51, the touch panel 52, a color filter 53, the counter resin substrate layer 54, a third adhesive layer 55, and a hard coat substrate 56, which are provided on a sealing film 19 in this order as shown in FIG. 11.

The second adhesive layer 51 is, for example, a UV post curable adhesive, a thermoset adhesive, an epoxy adhesive, an acrylic adhesive, or a polyolefin adhesive.

The touch panel 52 includes, for example, a base film, and a capacitive touch panel layer provided on the base film, and contains, as the main ingredient, a plastic film forming the base film. The plastic film is made of polyimide, polyethylene terephthalate, polyethylene naphthalate, aramid, (meth)acrylate, or any other suitable material.

The color filter 53 includes, for example, a black matrix layer formed in a grid pattern, a plurality of color resist layers, such as a red layer, a green layer, and a blue layer, each corresponding to one of the sub-pixels P, and an overcoat layer covering the black matrix layer and the color resist layers, and contains, as the main ingredient, a photosensitive acrylic resin, a photosensitive polyimide resin, a photosensitive polysiloxane resin, or any other suitable material.

The counter resin substrate layer 54 is configured as a plastic film made of, for example, polyimide, polyethylene terephthalate, polyethylene naphthalate, aramid, or (meth)acrylate.

The third adhesive layer 55 is made of, for example, a photo-curable adhesive sheet, a UV curable adhesive, a thermoset adhesive, an epoxy adhesive, or a cyanoacrylate instant adhesive.

The hard coat substrate 56 is configured as a plastic film made of, for example, polyimide, polyethylene terephthalate, polyethylene naphthalate, aramid, or (meth)acrylate.

The hard coat layer 58 is made of, for example, a UV curable organosilicon resin, a thermoset resin, an acrylic resin, an urethane resin, or a polysiloxane resin.

Just like the organic EL display device 100a of the first embodiment, the organic EL display device 100d configured as described above displays an image when the light-emitting layer 3 appropriately emits light in each of the sub-pixels P.

The organic EL display device 100d of this embodiment can be fabricated through appropriate modification of the method for fabricating the organic EL display device 100a of the first embodiment. Note that in the organic EL display device 100d, the stress adjusting layer 8, the first adhesive layer 9, the base resin substrate layer 10, the organic EL element layer 20, and the underlayer 57 form a stack layer Sd as shown in FIG. 11.

The organic EL display device 100d according to this embodiment is configured such that the difference between the Martens hardness HMh of the hard coat layer 58 alone and the weighted average Martens hardness HMa of the components of the stack layer Sd by the stress dispersion coefficients α of the components is less than or equal to 79 N/mm². If the difference between the Martens hardness HMh of the hard coat layer 58 alone and the weighted average Martens hardness HMa of the components of the stack layer Sd by the stress dispersion coefficients α exceeds 79 N/mm², a semipermanent plastic deformation (flaw) on a surface of the hard coat layer 58 tends to be visually identified.

The stress dispersion coefficient α of each component for use to calculate the weighted average Martens hardness is determined by the following formulae.

α=1.5×10⁻⁷x³+8.6×10⁻⁵x²−1.7×10⁻²x+1.45

where x is the distance (μm) from a surface (an upper surface) of the hard coat layer 58 remote from the underlayer 57 to the centerline of the component orthogonal to the thickness direction, and is less than or equal to 300; and

α=0

where x is greater than 300.

The thickness d, Young's modulus E, Martens hardness HM, and stress dispersion coefficient α of each of components of a structure including a stack, such as the organic EL element layer 20 or the underlayer 57, are determined. The determined Martens hardness HM and stress dispersion coefficient α are appropriately substituted into the following formula for calculating the weighted average Martens hardness, based on the magnitude of the ratio d/E of the thickness d to the Young's modulus E.

HMa=(α₁HM₁+α₂HM₂+ . . . +αₙHMₙ)/(α₁+α₂+ . . . +αₙ)

Next, an experiment which was actually conducted will be described.

An organic EL display device 100d configured as indicated below was fabricated as an example of this embodiment (a fourth example) (see the table shown in FIG. 12). The names and other features of materials described below are the names and other features of corresponding materials used to determine their actual thicknesses d, Young's moduli E, Martens hardnesses HM, and stress dispersion coefficients α.

Stress Adjusting Layer 8: a polyethylene terephthalate film with a thickness of 10.0 μm
First Adhesive Layer 9: an epoxy resin adhesive with a thickness of 10.0 μm (made by Alteco Co., Ltd.)
Base Resin Substrate Layer 10: a non-photosensitive polyimide resin coating with a thickness of 10.0 μm (PIQ (registered trademark) series made by Hitachi Chemical DuPont Microsystems Ltd)
Moisture-Proof Layer: a silicon nitride film with a thickness of 1.0 μm, formed by plasma CVD (chemical vapor deposition) (Young's modulus: 240.0 GPa)
First TFT 13a and Other Transistors: A configuration for a typical bottom gate TFT with a total thickness of 0.3 μm, which includes a wiring layer configured as a Ti/Al/Ti or Al/Ti multilayer film (Young's modulus: 200.0 GPa)
Interlayer Insulating Film 14: a photosensitive acrylic resin with a thickness of 2.5 μm (Optomer (registered trademark) series made by JSR Corporation)
First Electrode 15: an ITO/Ag multilayer film with a thickness of 0.1 μm, formed by a typical TFT process (Young's modulus: 200.0 GPa)
Edge Cover 16: a photosensitive acrylic resin with a thickness of 1.5 μm (Optomer (registered trademark) series made by JSR Corporation)
Organic EL Layer 17: a configuration of a typical organic EL element with a total thickness of 0.2 μm (Young's modulus: 2.0 GPa)
Second Electrode 18: an Ag film with a thickness of 0.1 μm, formed by an evaporation method (Young's modulus: 200.0 GPa)
Sealing Film 19: a silicon nitride film with a thickness of 3.0 μm, formed by low-temperature plasma CVD (Young's modulus: 80.0 GPa)
Second Adhesive Layer 51: a UV post curable adhesive with a thickness of 5.0 μm (Photorec (registered trademark) E series made by SEKISUI CHEMICAL CO., LTD.)
Touch Panel 52: a photosensitive acrylic resin with a thickness of 15.0 μm (Optomer (registered trademark) series made by JSR Corporation)
Color Filter 53: a photosensitive color filter resin with a thickness of 5.0 μm (COLOR MOSAIC (registered trademark) series made by Fujifilm Corporation)
Counter Resin Substrate Layer 54: a non-photosensitive polyimide resin coating with a thickness of 10.0 μm (PIQ (registered trademark) series made by Hitachi Chemical DuPont Microsystems Ltd)
Third Adhesive Layer 55: an epoxy resin adhesive with a thickness of 5.0 μm (made by Alteco Co., Ltd.)
Hard Coat Substrate 56: a polyethylene terephthalate film with a thickness of 25.0 μm
Hard Coat Layer 58: a UV curable organosilicon resin with a thickness of 10.0 μm
   The ratio d/E of each of the moisture-proof layer, the first TFT 13a, other transistors, the first electrode 15, the organic EL layer 17, the second electrode 18, and the sealing film 19 forming the organic EL element layer 20 is less than or equal to 1/100 of the sum total of these ratios d/E (24.2 μm/GPa). Thus, these ratios are omitted from the table shown in FIG. 12, and the weighted average Martens hardness HMa was calculated without reflecting these ratios.

In the fabricated organic EL display device 100d, the difference between the Martens hardness HMh of the hard coat layer 58 alone and the weighted average Martens hardness HMa of the components of the stack layer Sd was 65 N/mm² as shown in the table in FIG. 12. Even after the upper surface of the hard coat layer 58 was pressed under a high pressure (e.g., 90 MPa), a semipermanent plastic deformation (flaw) on the device surface (the surface of the hard coat layer 58) was hardly visually identified.

As can be seen, the organic EL display device 100d of this embodiment can provide the following advantages.

The difference between the Martens hardness HMh of the hard coat layer 58 alone and the weighted average Martens hardness HMa of the components of the stack layer Sd, which includes the base resin substrate layer 10, the organic EL element layer 20, and the underlayer 57, by the stress dispersion coefficients α of the components is less than or equal to 79 N/mm². This can reduce plastic deformation of the hard coat layer 58 forming the surface of the organic EL display device 100d. This reduces the degree to which the reflection of natural light entering a display screen of the organic EL display device 100d or light emitted from the organic EL element layer 20 scatters in the surface of the hard coat layer 58. Thus, the display quality of the organic EL display device 100d can be maintained.

The organic EL display device 100d includes the touch panel 52 provided between the base resin substrate layer 10 and the counter resin substrate layer 54. This allows the touch panel 52 and the color filter 53 to be formed together on the counter resin substrate layer 54, and can reduce manufacturing cost.

### Fifth Embodiment

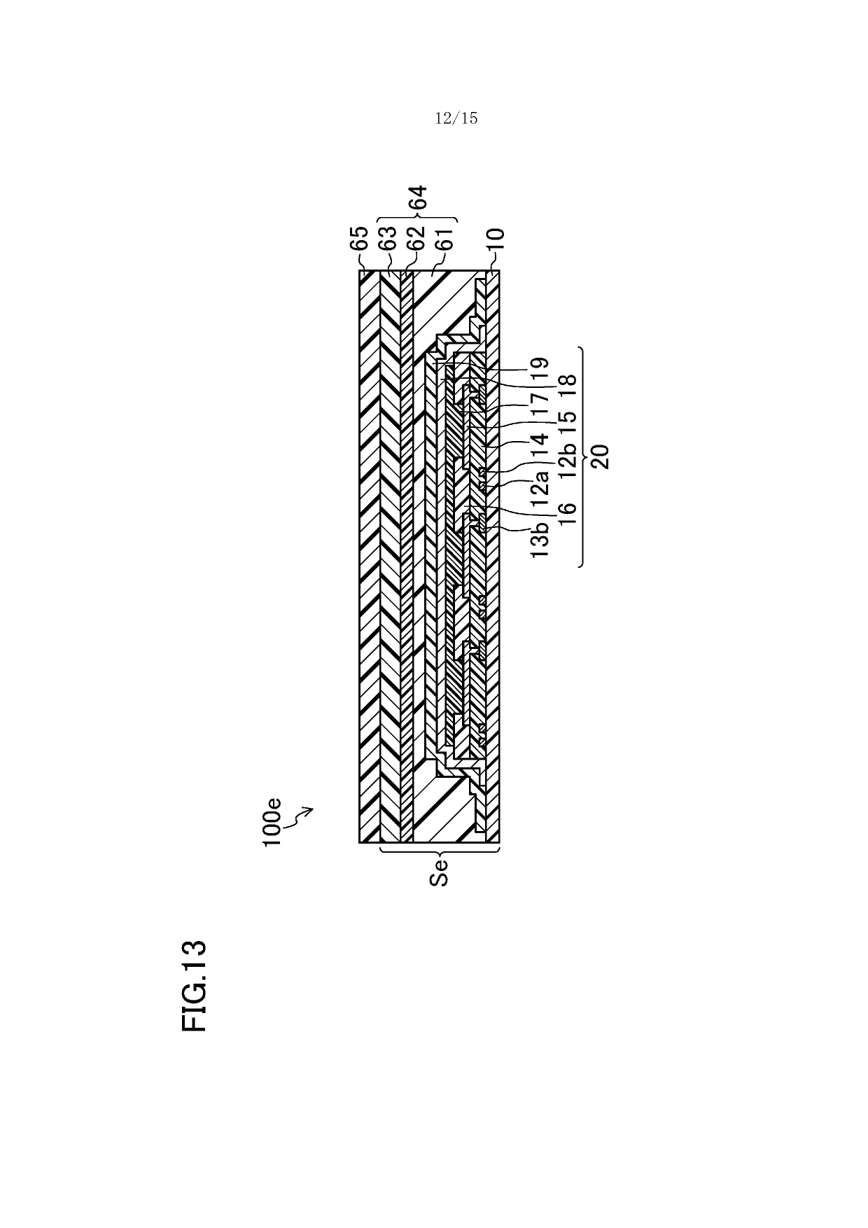

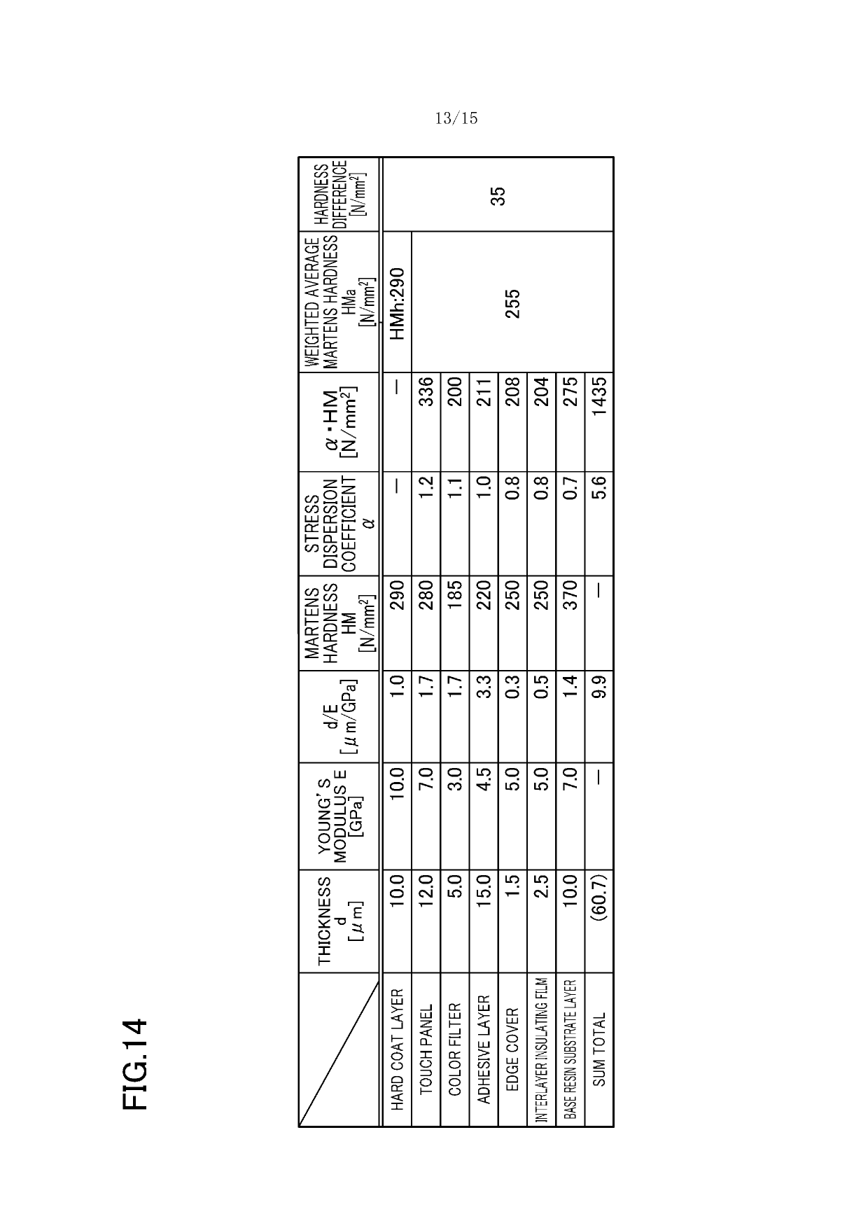

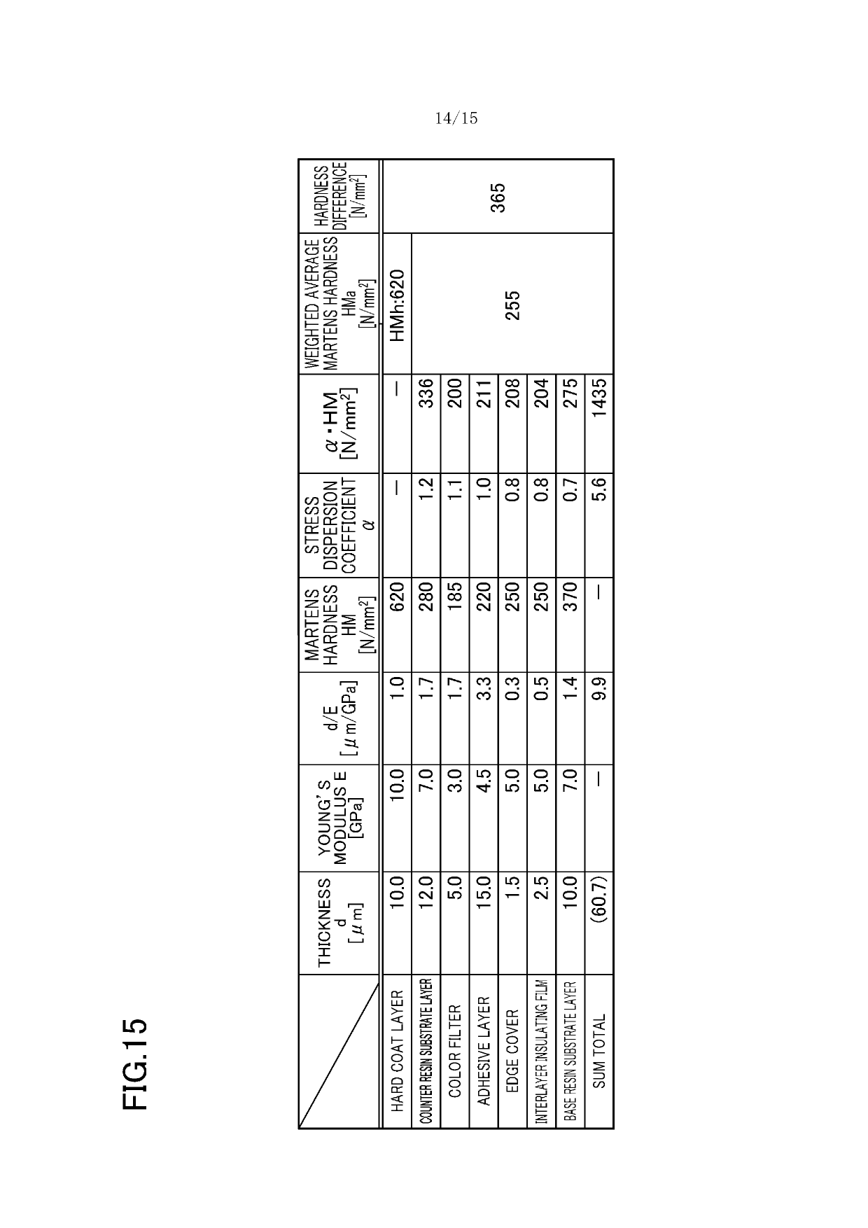

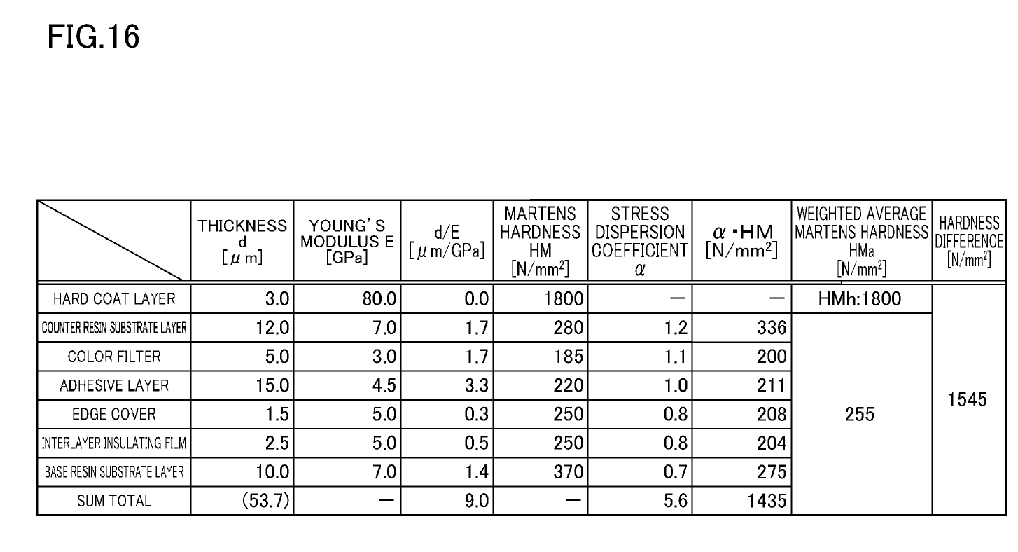

FIGS. 13 to 16 show an organic EL display device according to a fifth embodiment of the present invention. Here, FIG. 13 is a cross-sectional view of an organic EL display device 100e according to this embodiment. FIG. 14 is a table showing specific information on the organic EL display device 100e fabricated as a fifth example. FIG. 15 is a table showing specific information on a first comparative example of the organic EL display device 100e. FIG. 16 is a table showing specific information on a second comparative example of the organic EL display device 100e.

In the first through fourth embodiments, the organic EL display devices 100a through 100d each including the stress adjusting layer 8 provided on the back surface of the base resin substrate layer 10 have been exemplified. On the other hand, in this embodiment, the organic EL display device 100e that does not include a stress adjusting layer is exemplified.

As shown in FIG. 13, the organic EL display device 100e includes the base resin substrate layer 10, an organic EL element layer 20 provided on an upper surface of the base resin substrate layer 10 in this drawing, an underlayer 64 provided on the organic EL element layer 20, and a hard coat layer 65 provided on the underlayer 64. Note that the structure of each of pixels arranged in a display region of the organic EL display device 100e is substantially the same as that of each of the pixels arranged in a display region of the organic EL display device 100a of the first embodiment.

The underlayer 64 includes an adhesive layer 61, a color filter 62, and a touch panel 63, which are provided on a sealing film 19 in this order as shown in FIG. 13.

The adhesive layer 61 is, for example, a UV post curable adhesive, a thermoset adhesive, an epoxy adhesive, an acrylic adhesive, or a polyolefin adhesive.

The color filter 62 includes, for example, a black matrix layer formed in a grid pattern, a plurality of color resist layers, such as a red layer, a green layer, and a blue layer, each corresponding to one of the sub-pixels P, and an overcoat layer covering the black matrix layer and the color resist layers, and contains, as the main ingredient, a photosensitive acrylic resin, a photosensitive polyimide resin, a photosensitive polysiloxane resin, or any other suitable material. The color filter 62 is bonded onto the touch panel 63.

The touch panel 63 includes, for example, a base film, and a capacitive touch panel layer provided on the base film, and contains, as the main ingredient, a plastic film forming the base film. The plastic film is made of polyimide, polyethylene terephthalate, polyethylene naphthalate, aramid, (meth)acrylate, or any other suitable material.

The hard coat layer 65 is made of, for example, a UV curable organosilicon resin, a thermoset resin, an acrylic resin, an urethane resin, or a polysiloxane resin.

Just like the organic EL display device 100a of the first embodiment, the organic EL display device 100e configured as described above displays an image when the light-emitting layer 3 appropriately emits light in each of the sub-pixels P.

The organic EL display device 100e of this embodiment can be fabricated through appropriate modification of the method for fabricating the organic EL display device 100a of the first embodiment. Note that in the organic EL display device 100e, the stress adjusting layer 8, the first adhesive layer 9, the base resin substrate layer 10, the organic EL element layer 20, and the underlayer 64 form a stack layer Se as shown in FIG. 13.

The organic EL display device 100e according to this embodiment is configured such that the difference between the Martens hardness HMh of the hard coat layer 65 alone and the weighted average Martens hardness HMa of the components of the stack layer Se by the stress dispersion coefficients α of the components is less than or equal to 79 N/mm². If the difference between the Martens hardness HMh of the hard coat layer 65 alone and the weighted average Martens hardness HMa of the components of the stack layer Se by the stress dispersion coefficients α exceeds 79 N/mm², a semipermanent plastic deformation (flaw) on a surface of the hard coat layer 65 tends to be visually identified.

The stress dispersion coefficient α of each component for use to calculate the weighted average Martens hardness is determined by the following formulae.

α=−1.5×10⁻⁷x³+8.6×10⁻⁵x²−1.7×10⁻²x+1.45

where x is the distance (μm) from a surface (an upper surface) of the hard coat layer 65 remote from the underlayer 64 to the centerline of the component orthogonal to the thickness direction, and is less than or equal to 300; and

α=0

where x is greater than 300.

The thickness d, Young's modulus E, Martens hardness HM, and stress dispersion coefficient α of each of components of a structure including a stack, such as the organic EL element layer 20 or the underlayer 64, are determined. The determined Martens hardness HM and stress dispersion coefficient α are appropriately substituted into the following formula for calculating the weighted average Martens hardness, based on the magnitude of the ratio d/E of the thickness d to the Young's modulus E.

HMa=(α₁HM₁+α₂HM₂+ . . . +αₙHMₙ)/α₁+α₂+ . . . +αₙ)

Next, an experiment which was actually conducted will be described.

An organic EL display device 100e configured as indicated below was fabricated as an example of this embodiment (a fifth example) (see the table shown in FIG. 14). The names and other features of materials described below are the names and other features of corresponding materials used to determine their actual thicknesses d, Young's moduli E, Martens hardnesses HM, and stress dispersion coefficients α.

Base Resin Substrate Layer 10: a non-photosensitive polyimide resin coating with a thickness of 10.0 μm (PIQ (registered trademark) series made by Hitachi Chemical DuPont Microsystems Ltd)
Moisture-Proof Layer: a silicon nitride film with a thickness of 1.0 μm, formed by plasma CVD (chemical vapor deposition) (Young's modulus: 240.0 GPa)
First TFT 13a and Other Transistors: A configuration for a typical bottom gate TFT with a total thickness of 0.3 μm, which includes a wiring layer configured as a Ti/Al/Ti or Al/Ti multilayer film (Young's modulus: 200.0 GPa)
Interlayer Insulating Film 14: a photosensitive acrylic resin with a thickness of 2.5 μm (Optomer (registered trademark) series made by JSR Corporation)
First Electrode 15: an ITO/Ag multilayer film with a thickness of 0.1 μm, formed by a typical TFT process (Young's modulus: 200.0 GPa)
Edge Cover 16: a photosensitive acrylic resin with a thickness of 1.5 μm (Optomer (registered trademark) series made by JSR Corporation)
Organic EL Layer 17: a configuration of a typical organic EL element with a total thickness of 0.2 μm (Young's modulus: 2.0 GPa)
Second Electrode 18: an Ag film with a thickness of 0.1 μm, formed by an evaporation method (Young's modulus: 200.0 GPa)
Sealing Film 19: a silicon nitride film with a thickness of 3.0 μm, formed by low-temperature plasma CVD (Young's modulus: 80.0 GPa)
Adhesive Layer 61: a UV post curable adhesive with a thickness of 15.0 μm (Photorec (registered trademark) E series made by SEKISUI CHEMICAL CO., LTD.)
Color Filter 62: a photosensitive color filter resin with a thickness of 5.0 μm (COLOR MOSAIC (registered trademark) series made by Fujifilm Corporation)
Touch Panel 63: a non-photosensitive polyimide resin coating with a thickness of 12.0 μm (PIQ (registered trademark) series made by Hitachi Chemical DuPont Microsystems Ltd)
Hard Coat Layer 65: a UV curable organosilicon resin with a thickness of 10.0 μm
   The ratio d/E of each of the moisture-proof layer, the first TFT 13a, other transistors, the first electrode 15, the organic EL layer 17, the second electrode 18, and the sealing film 19 forming the organic EL element layer 20 is less than or equal to 1/100 of the sum total of these ratios d/E (10.1 μm/GPa). Thus, these ratios are omitted from the table shown in FIG. 14, and the weighted average Martens hardness HMa was calculated without reflecting these ratios.

In the fabricated organic EL display device 100e, the difference between the Martens hardness HMh of the hard coat layer 65 alone and the weighted average Martens hardness HMa of the components of the stack layer Se was 35 N/mm² as shown in the table in FIG. 14. Even after the upper surface of the hard coat layer 65 was pressed under a high pressure (e.g., 90 MPa), a semipermanent plastic deformation (flaw) on the device surface (the surface of the hard coat layer 65) was hardly visually identified.

An organic EL display device corresponding to the organic EL display device 100e and configured as indicated below was fabricated as a first comparative example of this embodiment (see the table shown in FIG. 15). The names and other features of materials described below are the names and other features of corresponding materials used to determine their actual thicknesses d, Young's moduli E, Martens hardnesses HM, and stress dispersion coefficients α.

Base Resin Substrate Layer: a non-photosensitive polyimide resin coating with a thickness of 10.0 μm (PIQ (registered trademark) series made by Hitachi Chemical DuPont Microsystems Ltd)
Moisture-Proof Layer: a silicon nitride film with a thickness of 1.0 μm, formed by plasma CVD (chemical vapor deposition) (Young's modulus: 240.0 GPa)
First TFTs and Other Transistors: A configuration for a typical bottom gate TFT with a total thickness of 0.3 μm, which includes a wiring layer configured as a Ti/Al/Ti or Al/Ti multilayer film (Young's modulus: 200.0 GPa)
Interlayer Insulating Film: a photosensitive acrylic resin with a thickness of 2.5 μm (Optomer (registered trademark) series made by JSR Corporation)
First Electrode: an ITO/Ag multilayer film with a thickness of 0.1 μm, formed by a typical TFT process (Young's modulus: 200.0 GPa)
Edge Cover: a photosensitive acrylic resin with a thickness of 1.5 μm (Optomer (registered trademark) series made by JSR Corporation)
Organic EL Layer: a configuration of a typical organic EL element with a total thickness of 0.2 μm (Young's modulus: 2.0 GPa)
Second Electrode: an Ag film formed by an evaporation method and having a thickness of 0.1 μm (Young's modulus: 200.0 GPa)
Sealing Film: a silicon nitride film with a thickness of 3.0 μm, formed by low-temperature plasma CVD (Young's modulus: 80.0 GPa)
Adhesive Layer: a UV post curable adhesive with a thickness of 15.0 μm (Photorec (registered trademark) E series made by SEKISUI CHEMICAL CO., LTD.)
Color Filter: a photosensitive color filter resin with a thickness of 5.0 μm (COLOR MOSAIC (registered trademark) series made by Fujifilm Corporation)
Counter Resin Substrate Layer Corresponding to Touch Panel: a non-photosensitive polyimide resin coating with a thickness of 12.0 μm (PIQ (registered trademark) series made by Hitachi Chemical DuPont Microsystems Ltd)
Hard Coat Layer: a UV curable inorganic-organic composite resin with a thickness of 10.0 μm (Compobrid HUV series made by ATOMIX CO., LTD.)
   The ratio d/E of each of the moisture-proof layer, the first TFT, other transistors, the first electrode, the organic EL layer, the second electrode, and the sealing film forming the organic EL element layer is less than or equal to 1/100 of the sum total of these ratios d/E (10.1 μm/GPa). Thus, these ratios are omitted from the table shown in FIG. 15, and the weighted average Martens hardness HMa was calculated without reflecting these ratios.

In the fabricated organic EL display device, the difference between the Martens hardness HMh of the hard coat layer alone and the weighted average Martens hardness HMa of the components of the stack layer was 365 N/mm² as shown in the table in FIG. 15. After the upper surface of the hard coat layer was pressed under a high pressure (e.g., 90 MPa), a semipermanent plastic deformation (flaw) on the device surface (the surface of the hard coat layer) was visually identified.

An organic EL display device corresponding to the organic EL display device 100e and configured as indicated below was fabricated as a second comparative example of this embodiment (see the table shown in FIG. 16). The names and other features of materials described below are the names and other features of corresponding materials used to determine their actual thicknesses d, Young's moduli E, Martens hardnesses HM, and stress dispersion coefficients α.

Base Resin Substrate Layer: a non-photosensitive polyimide resin coating with a thickness of 10.0 μm (PIQ (registered trademark) series made by Hitachi Chemical DuPont Microsystems Ltd)
Moisture-Proof Layer: a silicon nitride film with a thickness of 1.0 μm, formed by plasma CVD (chemical vapor deposition) (Young's modulus: 240.0 GPa)
First TFTs and Other Transistors: A configuration for a typical bottom gate TFT with a total thickness of 0.3 μm, which includes a wiring layer configured as a Ti/Al/Ti or Al/Ti multilayer film (Young's modulus: 200.0 GPa)
Interlayer Insulating Film: a photosensitive acrylic resin with a thickness of 2.5 μm (Optomer (registered trademark) series made by JSR Corporation)
First Electrode: an ITO/Ag multilayer film with a thickness of 0.1 μm, formed by a typical TFT process (Young's modulus: 200.0 GPa)
Edge Cover: a photosensitive acrylic resin with a thickness of 1.5 μm (Optomer (registered trademark) series made by JSR Corporation)
Organic EL Layer: a configuration of a typical organic EL element with a total thickness of 0.2 μm (Young's modulus: 2.0 GPa)
Second Electrode: an Ag film formed by an evaporation method and having a thickness of 0.1 μm (Young's modulus: 200.0 GPa)
Sealing Film: a silicon nitride film with a thickness of 3.0 μm, formed by low-temperature plasma CVD (Young's modulus: 80.0 GPa)
Adhesive Layer: a UV post curable adhesive with a thickness of 15.0 μm (Photorec (registered trademark) E series made by SEKISUI CHEMICAL CO., LTD.)
Color Filter: a photosensitive color filter resin with a thickness of 5.0 μm (COLOR MOSAIC (registered trademark) series made by Fujifilm Corporation)
Counter Resin Substrate Layer Corresponding to Touch Panel: a non-photosensitive polyimide resin coating with a thickness of 12.0 μm (PIQ (registered trademark) series made by Hitachi Chemical DuPont Microsystems Ltd)
Hard Coat Layer: a silicon nitride film with a thickness of 3.0 μm, formed by low-temperature plasma CVD
   The ratio d/E of each of the moisture-proof layer, the first TFT, other transistors, the first electrode, the organic EL layer, the second electrode, and the sealing film forming the organic EL element layer is less than or equal to 1/100 of the sum total of these ratios d/E (9.1 μm/GPa). Thus, these ratios are omitted from the table shown in FIG. 16, and the weighted average Martens hardness HMa was calculated without reflecting these ratios.

In the fabricated organic EL display device, the difference between the Martens hardness HMh of the hard coat layer alone and the weighted average Martens hardness HMa of the components of the stack layer was 1545 N/mm² as shown in the table in FIG. 16. After the upper surface of the hard coat layer was pressed under a high pressure (e.g., 90 MPa), a semipermanent plastic deformation (flaw) on the device surface (the surface of the hard coat layer) was visually identified.

As can be seen, the organic EL display device 100e of this embodiment can provide the following advantages.

The difference between the Martens hardness HMh of the hard coat layer 65 alone and the weighted average Martens hardness HMa of the components of the stack layer Se, which includes the base resin substrate layer 10, the organic EL element layer 20, and the underlayer 64, by the stress dispersion coefficients α of the components is less than or equal to 79 N/mm². This can reduce plastic deformation of the hard coat layer 65 forming the surface of the organic EL display device 100e. This reduces the degree to which the reflection of natural light entering a display screen of the organic EL display device 100e or light emitted from the organic EL element layer 20 scatters in the surface of the hard coat layer 65. Thus, the display quality of the organic EL display device 100e can be maintained.

A counter resin substrate layer and a stress adjusting layer are omitted from the organic EL display device 100e, and the hard coat layer 65 is configured as a single layer. This can reduce the thickness of the organic EL display device 100e, the costs of the components, and manufacturing cost.

### Other Embodiments

In each of the above embodiments, the organic EL layer has been exemplified as a layer having a stacked structure of the five layers, namely, the positive hole injection layer, a positive hole transport layer, the light-emitting layer, the electron transport layer, and the electron injection layer. Alternatively, the organic EL layer may have a stacked structure of three layers including a positive hole injection and transport layer, a light-emitting layer, and an electron transport and injection layer, for example.

In each of the above embodiments, the organic EL display device in which the first electrode functions as the anode and the second electrode functions as the cathode has been exemplified. Alternatively, the present invention is applicable to an organic EL display device in which the stacked structure of the organic EL element is inverted, the first electrode functions as the cathode, and the second electrode functions as the anode.

In each of the above embodiments, the organic EL display device including the TFT having, as the drain electrode, an electrode connected to the first electrode has been exemplified. Alternatively, the present invention is applicable to an organic EL display device including the TFT having an electrode connected to the first electrode and called a source electrode.

In the above embodiments, the organic EL display devices 100a to 100e have been exemplified. Alternatively, the present invention is applicable to an organic EL display device including any combination of two or more of the stacks of the exemplified organic EL display devices 100a to 100e.

### INDUSTRIAL APPLICABILITY

As can be seen from the foregoing description, the present invention is useful for a flexible organic EL display device.

### DESCRIPTION OF REFERENCE CHARACTERS

Sa to Se Stack Layer
V Vickers Indenter
8 Stress Adjusting Layer
10 Base Resin Substrate Layer
20 Organic EL Element Layer
22, 33, 54 Counter Resin Substrate Layer
24 Polarizing Plate
26, 35, 43, 52, 63 Touch Panel
29, 38, 46, 57, 64 Underlayer
30, 39, 47, 58, 65 Hard Coat Layer
32, 42, 53, 62 Color Filter
100a to 100e Organic EL Display Device

1. An organic EL display device comprising:
a base resin substrate layer;
an organic EL element layer provided on the base resin substrate layer;
an underlayer provided on the organic EL element layer; and
a hard coat layer provided on the underlayer, wherein
a difference between a Martens hardness of the hard coat layer alone and a weighted average Martens hardness of components of a stack layer by stress dispersion coefficients of the components is less than or equal to 79 N/mm², the stack layer including the base resin substrate layer, the organic EL element layer, and the underlayer.

2. The device of claim 1, wherein
a stress adjusting layer is provided on a side of the base resin substrate layer remote from the organic EL element layer, and
the stack layer includes the stress adjusting layer.

3. The device of claim 1, wherein
the Martens hardness of the hard coat layer alone and Martens hardnesses of the components are each defined by F/(26.43 h²), where h is a maximum indentation depth (mm) to which a Vickers indenter can be pressed against an associated one of the hard coat layer and the components by nanoindentation under a load F of 3 mN to 6 mN,
the stress dispersion coefficient α of each component is determined by the following formulae:
α=−1.5×10⁻⁷x³+8.6×10⁻⁵x²−1.7×10⁻²x+1.45
where x is a distance (μm) from a surface of the hard coat layer remote from the underlayer to a centerline of the component orthogonal to a thickness direction, and is less than or equal to 300; and
α=0
where x is greater than 300.

4. The device of claim 1, wherein
the underlayer includes a polarizing plate.

5. The device of claim 1, wherein
the underlayer includes a color filter.

6. The device of claim 5, wherein
the underlayer includes a counter resin substrate layer facing the base resin substrate layer, and a touch panel bonded to the counter resin substrate layer.

7. The device of claim 5, wherein
the underlayer includes a counter resin substrate layer facing the base resin substrate layer, and a touch panel provided between the counter resin substrate layer and the base resin substrate layer.

8. The device of claim 5, wherein
the underlayer includes a touch panel including the color filter facing the base resin substrate layer.
